(19) United States
(12) Patent Application Publication
(10) Pub. No.: US 2021/0003626 A1
(43) Pub. Date: Jan. 7, 2021

(54) METHOD FOR INACCURACY PREDICTION AND MITIGATION OF IMPEDANCE-BASED FAULT LOCATION IN DISTRIBUTION GRIDS

(71) Applicant: King Fahd University of Petroleum and Minerals, Dhahran (SA)

(72) Inventors: Mustafa Mohammed J. Al-Khabbaz, Dhahran (SA); Mohammad Abido, Dhahran (SA)

(73) Assignee: King Fahd University of Petroleum and Minerals, Dhahran (SA)

(21) Appl. No.: 16/502,796

(22) Filed: Jul. 3, 2019

(51) Int. Cl. G01R 31/08; G01R 25/00; G06F 17/11

(52) U.S. Cl. CPC G01R 31/086; G06F 17/11; G01R 25/005; G01R 31/088

(57) ABSTRACT

A method for predicting a fault location in a distribution system is provided. In the disclosed method, voltage signals and current signals are obtained from phasor measurement units (PMUs) placed at two terminals of a distribution line (DL) in the distribution system. The two terminals include a sending terminal and a receiving terminal. The voltage signals and current signals of the DL are converted into phasors. A fault type of a faulty line of the DL is subsequently classified in the distribution system based on the converted phasors. The fault type includes a symmetric type and an asymmetric type. A fault location of the faulty line of the DL is predicted based on the fault type through an impedance-based fault location model. Further, inaccuracy mitigation measures on the predicted fault location are applied to improve prediction accuracy.

### STATEMENT OF PRIOR DISCLOSURE BY AN INVENTOR

Method for inaccuracy prediction and mitigation of impedance-based fault location in distribution grids were described by Mustafa M. Al Khabbaz and Mohamed A. Abido in “Online Identification of Distribution Line Parameters by PMUs under Accuracy, Positive Sequence, and Noise Consideration”, Journal of Electrical and Computer Engineering Volume 2018, Article ID 8719670, 12 pages, published on Dec. 20, 2018, https://doi.org/10.1155/2018/8719670—incorporated herein by reference in its entirety.

### BACKGROUND

### Technical Field

The present disclosure is directed to a method for inaccuracy characterization and prediction, and mitigation of impedance-based fault location in distribution grids.

### Description of the Related Art

Fault location accuracy in distribution systems is an important aspect of fault location studies because the fault location accuracy can expedite line repair and system restoration, and subsequently shorten outage and interruption durations.

The majority of phasor measurement unit (PMU)—based fault location techniques were developed for transmission. Fault location applications of PMUs for distribution grids are very limited. Fault locations in distribution networks have the same criticality level, if not more, compared to transmission fault locations for the following four reasons.

Firstly, in numerous cases, distribution lines (DLs) are installed underground, especially in residential and industrial areas for different justifications. The justifications include safety risks associated with aerial lines, such as risks to people and buildings in cities. Underground installations usually cross roads and pass under third-party territories which makes coordination more complicated. This issue is exacerbated further by the fact that underground circuits require manual patrolling and inspection in case of maintenance or abnormal situations. Patrolling to inspect aerial transmission lines is performed by vehicles.

Secondly, live downed-conductors are common problems in distribution networks, which create a safety risk. Therefore, quick and accurate protection and fault location techniques are necessary.

Thirdly, transmission lines are designed with acceptable redundancy to tolerate planned and forced outages. Therefore, faults may cause line outages but do not necessarily cause power interruption to customers. Unlike transmission, most distribution circuits are designed to be radial type. Accordingly, any fault in the radial configuration DL can cause interruptions. These interruptions may cause a tremendous amount of opportunity loss and actual money loss.

Fourth, distribution system faults account for more than 80% of customer interruptions (See D. Chowdhury, Ali; Koval, Power distribution system reliability: practical methods and applications, Second. Wiley-Blackwell, 2009, incorporated herein by reference in its entirety). Such a big percentage confirms the high priority of fault location in distribution grids.

The above four considerations reflect the need for a swift and accurate fault location technique in distribution networks.

Conventional fault location methods used in distribution networks using PMUs can be organized into following four main categories.

In a first category, impedance-based methods consider fundamental voltage and current signals and network parameters to find the fault locations (See J. Ren, S. S. Venkata, and E. Sortomme, “An Accurate Synchrophasor Based Fault Location Method for Emerging Distribution Systems,” IEEE Trans. Power Deliv., vol. 29, no. 1, pp. 297-298, February 2014; Z. Mengsheng, W. Yi, Z. Zhou, and Z. Li, “Research on fault location based on PMU for multi-source distribution network,” in Asia-Pacific Power and Energy Engineering Conference, APPEEC, 2016, vol. 2016-Decem, pp. 1877-1882; A. Rajeev, T. S. Angel, and F. Z. Khan, “Fault location in distribution feeders with optimally placed PMU's,” in Proceedings of IEEE International Conference on Technological Advancements in Power and Energy, TAP Energy 2015, 2015, pp. 438-442; D. Patynowski et al., “Fault Locator approach for high-impedance grounded or ungrounded distribution systems using synchrophasors,” in 2015 68th Annual Conference for Protective Relay Engineers, CPRE 2015, 2015, pp. 302-310; M. M. Ghalei, H. K. Kargar, and M. G. M. M. G. M. Zanjani, “High impedance fault detection of distribution network by phasor measurement units,” in Electrical Power Distribution Networks (EPDC), 2012 Proceedings of 17th Conference on, 2012, no. Proceedings of 17th Conference on, pp. 1-5; J. Mora-Flòrez, J. Meléndez, and G. Carrillo-Caicedo, “Comparison of impedance based fault location methods for power distribution systems,” Electr. Power Syst. Res., vol. 78, no. 4, pp. 657-666, April 2008; K. Ramar and E. E. Ngu, “Generalized Impedance-Based Fault Location for Distribution Systems,” IEEE Trans. Power Deliv., vol. 27, no. 1, pp. 449-451, 2012; R. Dashti and J. Sadeh, “Accuracy improvement of impedance-based fault location method for power distribution network using distributed-parameter line model,” Int. Trans. Electr. Energy Syst., vol. 24, no. 3, 2014; R. Dashti and J. Sadeh, “Applying Dynamic Load Estimation and Distributed-parameter Line Model to Enhance the Accuracy of Impedance-based Fault-location Methods for Power Distribution Networks,” Electr. Power Components Syst., vol. 41, no. 14, pp. 1334-1362, 2013; S. F. Alwash and V. K. Ramachandaramurthy, “New impedance-based fault location method for unbalanced power distribution systems,” Int. Trans. Electr. Energy Syst., vol. 25, no. 6, pp. 1008-1021, 2015; R. H. Salim, K. C. O. Salim, and A. S. Bretas, “Further improvements on impedance-based fault location for power distribution systems,” IET Gener. Transm. Distrib., vol. 5, no. 4, pp. 467-478, 2011, each incorporated herein by reference in their entirety).

In a second category, travelling wave techniques utilize travelling waves of the voltage and current between the network terminals during the fault (See J. Lee, “Automatic Fault Location on Distribution Networks Using Synchronized Voltage Phasor Measurement Units,” in Volume 2: Simple and Combined Cycles; Advanced Energy Systems and Renewables (Wind, Solar and Geothermal); Energy Water Nexus; Thermal Hydraulics and CFD; Nuclear Plant Design, Licensing and Construction; Performance Testing and Performance Test Codes; St, 2014, vol. 2, p. V002T14A008; A. T. Jahromi, P. Wolfs, and S. Islam, “Travelling wave fault location in rural radial distribution networks to reduce wild fire risk,” in 2015 Australasian Universities Power Engineering Conference: Challenges for Future Grids, AUPEC 2015, 2015, pp. 1-6; A. T. Jahromi, “A Travelling Wave Detector Based Fault Location Device and Data Recorder for Medium Voltage Distribution Systems,” in 2016 Australasian Universities Power Engineering Conference (AUPEC), 2016, pp. 3-7; H. Ye, K. Rui, Z. Zhu, X. Zeng, D. Yang, and Y. Cao, “A novel single-phase grounding fault location method with traveling wave for distribution networks,” in 2015 5th International Conference on Electric Utility Deregulation and Restructuring and Power Technologies (DRPT), 2015, pp. 1175-1179; and J. Zhao, T. He, C.-M. Liu, and K. Li, “Travelling Wave Fault Location for Distribution Line Based on Improved Morphological Gradient Algorithm,” in 2016 International Symposium on Computer, Consumer and Control (IS3C), 2016, pp. 156-159, each incorporated herein by reference in their entirety).

In a third category, wavelets, which are mathematical models, are used for digital signal processing with similar principles to Fourier analysis (See E. S. Tag El Din, M. Gilany, M. M. Abdel Aziz, and D. K. Ibrahim, “An PMU double ended fault location scheme for aged power cables,” in IEEE Power Engineering Society General Meeting, 2005, 2005, pp. 423-429; and A. A. P. Bescaro, R. A. F. Pereira, and J. R. S. Mantovani, “Optimal Phasor Measurement Units Placement for fault location on overhead electric power distribution feeders,” in 2010 IEEE/PES Transmission and Distribution Conference and Exposition: Latin America (T&D-LA), 2010, pp. 37-43, each incorporated herein by reference in their entirety).

In a fourth category are other techniques based on different approaches. The other techniques are uncommonly used for fault location such as state estimation (See M. Pignati, L. Zanni, P. Romano, R. Cherkaoui, and M. Paolone, “Fault Detection and Faulted Line Identification in Active Distribution Networks Using Synchrophasors-Based Real-Time State Estimation,” IEEE Trans. Power Deliv., vol. 32, no. 1, pp. 381-392, February 2017; and R. A. F. Pereira, L. G. W. da Silva, and J. R. S. Mantovani, “PMUs optimized allocation using a tabu search algorithm for fault location in electric power distribution system,” in 2004 IEEE/PES Transmision and Distribution Conference and Exposition: Latin America (IEEE Cat. No. 04EX956), 2004, pp. 143-148, each incorporated herein by reference in their entirety).

In general, there is little effort devoted to impedance-based fault location applications of PMUs in distribution grids. Paper J. Ren et al. (See J. Ren, S. S. Venkata, and E. Sortomme, “An Accurate Synchrophasor Based Fault Location Method for Emerging Distribution Systems,” IEEE Trans. Power Deliv., vol. 29, no. 1, pp. 297-298, February 2014) present a method that works for different networks including active and passive, radial, and looped with ranging precision in order of magnitude of 1%. A new PMU-based method was introduced by Z. Mengsheng et al. (see Z. Mengsheng, W. Yi, Z. Zhou, and Z. Li, “Research on fault location based on PMU for multi-source distribution network,” in Asia-Pacific Power and Energy Engineering Conference, APPEEC, 2016, vol. 2016-Decem, pp. 1877-1882) to locate faults in distribution networks. The method is proven via simulations using MATLAB/Simulink for different types of faults. In Reference A. Rajeev (see A. Rajeev, T. S. Angel, and F. Z. Khan, “Fault location in distribution feeders with optimally placed PMU's,” in Proceedings of IEEE International Conference on Technological Advancements in Power and Energy, TAP Energy 2015, 2015, pp. 438-442), an algorithm for optimal PMU placement is validated for a 7-bus test circuit in addition to IEEE 14 and 30-bus networks. The optimal PMU placement is performed to identify the fault location in both a ring and a radial type of distribution system, which is tested by using 11-bus radial and 14-bus ring networks. Patynowski et al. (see D. Patynowski et al., “Fault Locator approach for high-impedance grounded or ungrounded distribution systems using synchrophasors,” in 2015 68th Annual Conference for Protective Relay Engineers, CPRE 2015, 2015, pp. 302-310) disclose a new approach that collects the data from different sources for high impedance grounded or ungrounded lines. A new algorithm for high impedance fault (HIF) was introduced by Kargar and Zanjani (see M. M. Ghalei, H. K. Kargar, and M. G. M. M. G. M. Zanjani, “High impedance fault detection of distribution network by phasor measurement units,” in Electrical Power Distribution Networks (EPDC), 2012 Proceedings of 17th Conference on 2012, no. Proceedings of 17th Conference on, pp. 1-5). This type of fault is difficult to detect by over-current protection relays because of low fault current. The algorithm is sensitive to any change in current phasor. The best accuracy of fault location studies in distribution networks that is achieved is 99.8% by E. S. Tag El Din et al. (See E. S. Tag El Din, M. Gilany, M. M. Abdel Aziz, and D. K. Ibrahim, “An PMU double ended fault location scheme for aged power cables,” in IEEE Power Engineering Society General Meeting, 2005, 2005, pp. 423-429). The method is based on a wavelet technique. The accuracy of J. Ren et al. (see J. Ren, S. S. Venkata, and E. Sortomme, “An Accurate Synchrophasor Based Fault Location Method for Emerging Distribution Systems,” IEEE Trans. Power Deliv., vol. 29, no. 1, pp. 297-298, February 2014) and Z. Mengsheng et al. (see Z. Mengsheng, W. Yi, Z. Zhou, and Z. Li, “Research on fault location based on PMU for multi-source distribution network,” in Asia-Pacific Power and Energy Engineering Conference, APPEEC, 2016, vol. 2016-December, pp. 1877-1882) are 99%, which is the highest for impedance-based fault location techniques in distribution networks.

A number of factors that influence fault location accuracy when impedance-based techniques are used have not been addressed. For example, some main factors can be identified as follows: a) inaccuracy of identifying fault types for fault-locating algorithms, which affects accuracy due to algorithm prejudices are only effective in certain fault types (i.e., a single line-to-ground fault (LG)); b) unaccepted deviation between the line parameters and the actual parameters, which could result from the total length of the line, and could be identified with errors, although the geometry of conductors and parameters are accurate; c) insufficient accuracy due to changes in the line parameters resulting from different conditions, such as weather conditions (i.e., snow, dusts, winter, and summer, etc.), loading conditions, and aging of the network; d) the uncertainty of the zero-sequence impedance when the zero-sequence impedance is impacted by soil resistivity, which varies under different conditions including the weather (e.g. rainy, sunny, and dry, etc.); e) the lack of accurate line models that take into account transposition, inhomogeneity, shunt admittance, mutual effects, and so on.

Accordingly, fixed line parameters can play a major role in increasing the calculation error. The accurate data of DL parameters improves the precision of locating faults.

The present disclosure provides a method for inaccuracy characterization and prediction, and mitigation of impedance-based fault location in DLs by using PMUs. Swift and accurate fault location can advance restoration of faulty lines in an industry in which fault location depends heavily on manual foot patrols with electronic locators and fault finders (See T. W. Stringfield, D. J. Marihart, and R. F. Stevens, “Fault Location Methods for Overhead Lines,” Trans. Am. Inst. Electr. Eng. Part III Power Appar. Syst., vol. 76, no. 3, pp. 518-529, April 1957, incorporated herein by reference in its entirety). In the present disclosure, superposition is introduced. The superposition can be used in developing an asymmetrical fault location method. In addition, the line parameters are identified online through the voltage and current waves obtained from the installed PMUs, which can overcome the deficiencies associated with the fixed predefined line parameters. Further, a percentage error formula is provided, which can be applied along with other statistical measures to evaluate the effectiveness of proposed model in detecting the fault with high accuracy level under different scenarios. Developed case studies along with their results are also presented.

### SUMMARY

In the present disclosure, novel impedance-based fault location models for homogeneous distribution grids are proposed. The concept of accuracy improvement, namely inaccuracy mitigation measures (IMMs) have also been considered. The IMMs is introduced to reduce the error associated with the fault location estimation and so expedite power restoration. The model associated with homogeneous lines includes asymmetrical and symmetrical fault classification and location algorithms. The algorithms along with the mitigation measures have been evaluated by using different statistical measures. A total of 7,254 different case studies have been simulated and analyzed for different scenarios, cases, fault types and fault distances.

The inputs of the model are calculated online by using voltage and current signals obtained from PMUs placed at the line two terminals.

According to an aspect of the disclosure, a method for predicting a fault location in a distribution system is provided. In the disclosed method, voltage signals and current signals are obtained from phasor measurement units (PMUs) placed at two terminals of a distribution line (DL) in the distribution system. The two terminals include a sending terminal and a receiving terminal. The voltage signals and current signals of the DL are converted into phasors. A fault type of a faulty line of the DL is subsequently classified in the distribution system based on the converted phasors. The fault type includes a symmetric type and an asymmetric type. A fault location of the faulty line of the DL is predicted based on the fault type through an impedance-based fault location model. Further, inaccuracy mitigation measures on the predicted fault location are applied to improve prediction accuracy.

In some embodiments, when the fault type is the symmetric type, the predicting the fault location of the faulty line of the DL further includes calculating parameters of the faulty lines, and applying an symmetric method of the impedance-based fault location model on the calculated parameters to predict the fault location of the faulty line.

In some embodiments, when the fault type is the asymmetric type, the predicting the fault location of the faulty line of the DL further includes calculating parameters of the faulty lines, determining symmetrical components of the voltage signals and current signals of the DL, identifying superposed quantities of the voltage signals and current signals of the DL, determining an equivalent impedance of a source and an equivalent impedance of a load in the faulty line of the DL, and applying an asymmetric method of the impedance-based fault location model onto the calculated parameters, the identified symmetrical components, the determined superposed quantities, and the determined equivalent impedances to predict the fault location of the faulty line.

In some embodiments, the inaccuracy mitigation measures includes ÿ=\dot{y}(1+ε(\dot{y})). \dot{y} is an originally predicted value of the fault location based on the impedance-based fault location model. ÿ is an enhanced prediction, and ε(\dot{y}) is taken from pre-developed inaccuracy mitigation measures in which the originally predicted value \dot{y} corresponds to a respective value of ε.

According to another aspect of the disclosure, an apparatus is provided. The apparatus has processing circuitry. The processing circuitry is configured to perform the disclosed method for predicting a fault location in a distribution system.

Aspects of the disclosure also provide a non-transitory computer-readable medium storing instructions which when executed by a computer cause the computer to perform the method mentioned above.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a superposed network of a distribution system, in accordance with some embodiments.

FIG. 2 is a flowchart of a process to implement a proposed impedance-based fault location method, in accordance with some embodiments.

FIG. 3 is a schematic diagram of a distribution network for symmetric algorithm, in accordance with some embodiments.

FIG. 4A is an indicative graph of a proposed inaccuracy mitigation measurement, in accordance with some embodiments.

FIG. 4B is another indicative graph of the proposed inaccuracy mitigation measurement, in accordance with some embodiments.

FIG. 5 is a schematic diagram of an apparatus for predicting a fault location in a distribution system, in accordance with some embodiments.

FIG. 6 is a block diagram illustrating an exemplary electronic device, in accordance with some embodiments.

FIG. 7 is a block diagram of a hardware description of a processor, in accordance with some embodiments.

FIG. 8 is a schematic diagram of an exemplary data processing system, in accordance with some embodiments.

FIG. 9 illustrates an implementation of a CPU, in accordance with some embodiments.

FIG. 10 illustrates an exemplary cloud computing system, in accordance with some embodiments.

FIG. 11 is an exemplary test distribution network, in accordance with some embodiments.

FIG. 12 illustrates voltage and current signals obtained from PMU devices at a sending terminal, in accordance with some embodiments.

FIG. 13 illustrates voltage and current signals obtained from PMU devices at a receiving terminal, in accordance with some embodiments.

FIG. 14A illustrates calculation average errors of fault resistances for a first asymmetric scenario under a base case, in accordance with some embodiments.

FIG. 14B illustrates calculation average errors of fault resistances for a second asymmetric scenario under a base case, in accordance with some embodiments.

FIG. 14C illustrates calculation average errors of fault resistances for a third asymmetric scenario under a base case, in accordance with some embodiments.

FIG. 15 illustrates a fault location solution for a line-to-ground (AG) fault, in accordance with some embodiments.

FIG. 16A illustrates calculation average errors of fault resistances for a first asymmetric scenario under a global-based inaccuracy mitigation measure (GIMM), in accordance with some embodiments.

FIG. 16B illustrates calculation average errors of fault resistances for a second asymmetric scenario under a global-based inaccuracy mitigation measure (GIMM), in accordance with some embodiments.

FIG. 16C illustrates calculation average errors of fault resistances for a third asymmetric scenario under a global-based inaccuracy mitigation measure (GIMM), in accordance with some embodiments.

FIG. 17A illustrates calculation average errors of fault resistances for a first asymmetric scenario under a local-based inaccuracy mitigation measure (LIMM), in accordance with some embodiments.

FIG. 17B illustrates calculation average errors of fault resistances for a second asymmetric scenario under a local-based inaccuracy mitigation measure (LIMM), in accordance with some embodiments.

FIG. 17C illustrates calculation average errors of fault resistances for a third asymmetric scenario under a local-based inaccuracy mitigation measure (LIMM), in accordance with some embodiments.

FIG. 18A illustrates calculation average errors of fault resistances for a first symmetric scenario under a base case, in accordance with some embodiments.

FIG. 18B illustrates calculation average errors of fault resistances for a second symmetric scenario under a base case, in accordance with some embodiments.

FIG. 18C illustrates calculation average errors of fault resistances for a third symmetric scenario under a base case, in accordance with some embodiments.

FIG. 19A illustrates calculation average errors of fault resistances for a first symmetric scenario under an inaccuracy mitigation measure, in accordance with some embodiments.

FIG. 19B illustrates calculation average errors of fault resistances for a second symmetric scenario under an inaccuracy mitigation measure, in accordance with some embodiments.

FIG. 19C illustrates calculation average errors of fault resistances for a third symmetric scenario under an inaccuracy mitigation measure, in accordance with some embodiments.

### DETAILED DESCRIPTION

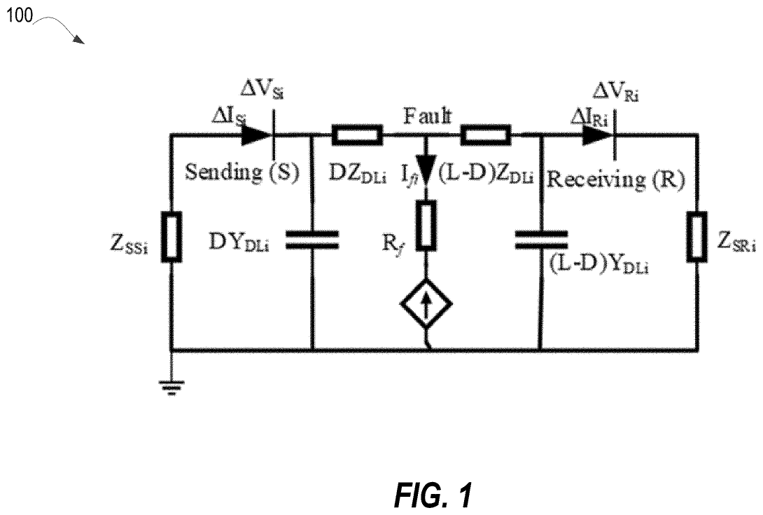

Linear systems obey a superposition principle, which separates the faulty system (post-fault) into two circuits: steady state (pre-fault) and during fault circuits (See J. J. Grainer and W. Stevenson, Power System Analysis. McGraw-Hill, 1994, incorporated herein by reference in its entirety). The superposition principle results in a new circuit called a superposed network (e.g., a superposed distribution system for electrical distribution). The superposed distribution system is converted into a sequence electrical distribution system that is illustrated in FIG. 1.

As shown in FIG. 1, parameters of FIG. 1 can be described. i can be zero, positive and negative sequences (i=0,1,2). Z_{SSi} is an equivalent i^{th} sequence source impedance at the sending end (terminal). Z_{SRi} is an equivalent i^{th} sequence source impedance at the receiving end (terminal). Z_{DL} is a i^{th} sequence of distribution line impedance. Y_{DL} is a i^{th} sequence of distribution line admittance. R is a fault resistance. I_{fi} is a i^{th} sequence of the fault current. ΔV_{Si} is a i^{th} sequence of superposed voltage at sending end (terminal). ΔV_{Ri} is a i^{th} sequence of superposed voltage at receiving end (terminal). ΔI_{Si} is a i^{th} sequence of superposed current at sending end. ΔI_{Ri} is a i^{th} sequence of superposed current at receiving end. L is a total distribution line length. D is a distance of the fault from the sending end.

Consider dV_{Sk} and dI_{Sk} to be a superposed phase voltage and a phase current at a sending terminal of a distribution line (DL) respectively, and dV_{Rk} and dI_{Rk} to be a superposed phase voltage and a phase current at a receiving terminal of the DL respectively, where k reflects the phase a, b or c. Applying concepts of symmetrical components transformation method, the following yields:

ΔV_{Si}=M⁻¹×dV_{Sk} (1)

ΔV_{Ri}=M⁻¹×dV_{Rk} (2)

ΔI_{Si}=M⁻¹×dI_{Sk} (3)

ΔI_{Ri}=M⁻¹×dI_{Rk} (4)

Where, M⁻¹ is a reciprocal of M. M is known as a symmetrical component transformation matrix (SCTM), which converts the phasor quantities into their symmetrical components. The M⁻¹ can be described as follows:

$$\begin{matrix}{M}^{- 1} = \frac{1}{3} [ \begin{matrix}1 & 1 & 1 \\ 1 & a & {a}^{2} \\ 1 & {a}^{2} & a\end{matrix} ] & ( 5 ) \\ a = 1 {e}^{i {120}^{°}} & ( 6 )\end{matrix}$$

Z_{SSi} and Z_{SRi} are equivalent impedances at the source (sending) and load (receiving) sides (terminals), respectively. Values of the Z_{SSi} and Z_{SRi} can be directly related to a change of generation mode and a load of the distribution system. In the present disclosure, the equivalent impedances Z_{SSi} and Z_{SRi} can be obtained from an administration agency, such as a Power Bureau, and the equivalent impedances Z_{SSi} and Z_{SRi} can change with time. However, it is beneficial to calculate the equivalent impedances Z_{SSi} and Z_{SRi} online in order to apply the equivalent impedances Z_{SSi} and Z_{SRi} in a fault location model to reflect more practical and synchronized values. In the present disclosure, the equivalent impedances Z_{SSi} and Z_{SRi} can be calculated online at the two terminals of the DL by using the superposed sequence voltage and current phasors. From FIG. 1, the equivalent impedances Z_{SSi} and Z_{SRi} can be estimated by applying Kirchhoff Laws as follows:

$$\begin{matrix}{Z}_{S S i} = \frac{Δ {V}_{S i}}{Δ {I}_{S i}} & ( 7 ) \\ {Z}_{S R i} = \frac{Δ {V}_{R i}}{Δ {I}_{R i}} & ( 8 )\end{matrix}$$

The equivalent impedances Z_{SSi} and Z_{SRi} can reflect the generation and load modes of the distribution grids during faults.

By utilizing a superposition system configuration such as that shown in FIG. 1 in determining a fault location, the effects of the distribution system pre-fault conditions on the accuracy of the determination of the fault location can be reduced.

In the present disclosure, to overcome line parameters related influencing factors on the accuracy of the determination of the fault location, the line parameters can be identified online through the distribution line (DL). Identification of the line parameters is based on voltage and current signals obtained from PMUs that are placed at the two terminals of the DL. A ±20% inaccuracy of line parameters could result in substantial errors in determining fault location. The resulted error can reach up to 6.6% as per Joe-Air Jiang et al. (See Joe-Air Jiang, Jun-Zhe Yang, Ying-Hong Lin, Chih-Wen Liu, and Jih-Chen Ma, “An adaptive PMU based fault detection/location technique for transmission lines. I. Theory and algorithms,” IEEE Trans. Power Deliv., vol. 15, no. 2, pp. 486-493, April 2000, incorporated herein by reference in its entirety).

In the present disclosure, a single measurement technique (SMT) can be used to identify a DL resistance, a reactive inductance and a shunt admittance. A DL capacitance can also be considered despite the fact that the DL capacitance does not play the same role as in electrical power studies in electrical power transmission. A consideration of the DL capacitance can ensure that a high accuracy is maintained. The SMT can apply symmetrical components of the voltage and current signals that are obtained from PMUs at the steady state. The SMT equations are formulated as follows:

$$\begin{matrix}{Z}_{D L i} = \frac{{V}_{S i}^{2} - {V}_{R i}^{2}}{{V}_{Ri} {I}_{S i} + {V}_{Si} {I}_{R i}} & ( 9 ) \\ {Y}_{D L i} = \frac{2 ( {V}_{S i} - {V}_{R i} )}{{I}_{Ri} + {I}_{Si}} & ( 10 )\end{matrix}$$

As shown in equations (9) and (10), Z_{DLi} can be a i^{th} sequence of distribution line impedance. V_{Si} can be a i^{th} sequence of voltage collected from the PMUs at the sending terminal. V_{Ri} can be a i^{th} sequence of voltage collected from the PMUs at the receiving terminal. I_{Si} can be a i^{th} sequence of current collected from the PMUs at the sending terminal. I_{Ri} can be a i^{th} sequence of current collected from the PMUs at the receiving terminal. Y_{DLi} can be a i^{th} sequence of distribution line admittance.

The effectiveness of the SMT method in finding the symmetrical components of DL parameters has been investigated by M. M. Al-khabbaz (See, M. M. Al-khabbaz, “Fault Location In Power Distribution Grids Using Phasor Measurement Units,” King Fahd University Of Petroleum & Minerals, 2018, incorporated herein by reference in its entirety).

In some embodiments, as show in equations (9) and (10), the pre-fault symmetrical components of voltage and current at the sending and receiving ends can be used in the determination of the line parameters. In some embodiments, in case of symmetrical faults, either phase or positive-sequence voltage and current quantities can be used to find the phase line parameters, which is recommended by M. M. Al-khabbaz (See, M. M. Al-khabbaz, “Fault Location In Power Distribution Grids Using Phasor Measurement Units,” King Fahd University Of Petroleum & Minerals, 2018, incorporated herein by reference in its entirety).

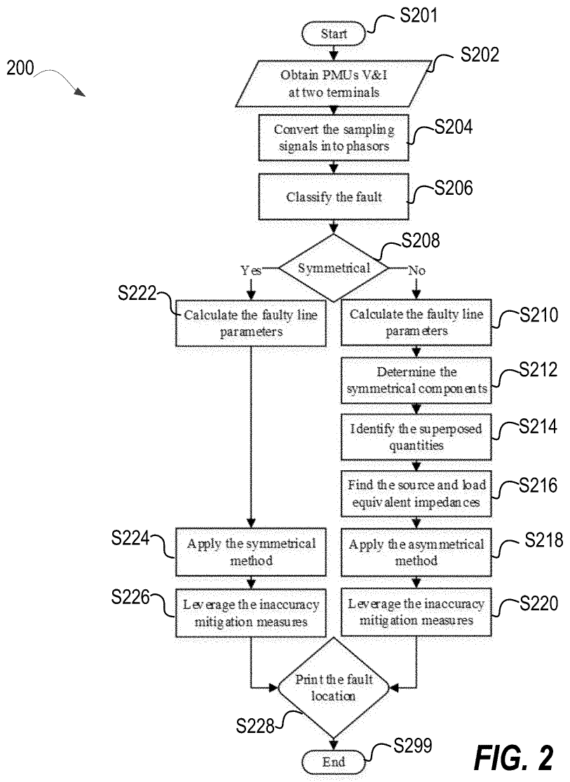

The impedance-based fault location method for distribution grids of the invention which uses PMUs is demonstrated in FIG. 2. The method includes an asymmetric impedance-based fault location method applied to asymmetric faults, and a symmetric impedance-based fault location method applied to symmetric faults.

FIG. 2 is a flowchart of a process 200 that implements the impedance-based fault location method of the invention. The process 200 can start from step S202, where the voltage signals and current signals of the sending terminal and receiving terminal of the DL can be obtained from the PMUs.

At step S204, the obtained voltage and current signals can be converted into phasors. For example, a four-sample method (see D. M. Abido, “EE541 Power System Protection II (Course Handouts).” Dhahran, p. 150, 2010) can be used to convert the obtained voltage and current signals into phasors. In some embodiments, the four-sample method is similar to Fourier analysis in term of obtaining the fundamental (60 Hz) component from noisy signals. The advantage of using the four-sample method is its simplicity and no need for using trigonometric functions.

At step S206, a fault type of a faulty line of the DL in the distribution system can be classified based on the converted phasors. The fault type can include a symmetric type and an asymmetric type. In some embodiments, for the symmetrical fault, all phases are short-circuited to each other and often to earth. The symmetric fault is balanced in a sense that the systems remain symmetrical, or the lines are displaced by an equal angle (i.e. 1200 in three phase line). The symmetrical fault is a most severe type of fault involving largest current, but symmetrical faults rarely occur.

An asymmetrical fault can involve one or two phases. In the asymmetrical fault, the three phase lines become unbalanced. The asymmetrical fault can occur between line-to-ground or between lines. The asymmetric fault can include a series fault and/or a shunt fault. The asymmetrical series fault can occur between phases or between phase-to-ground. The asymmetrical shunt fault can be unbalanced in the line impedances. The asymmetric fault can include a single line-to-ground fault (LG), a line-to-line fault (LL), a double line-to-ground fault (LLG), and the symmetric fault can include a three-phase short circuit fault (LLL), and a three-phase-to-ground fault (LLLG).

In the single line-to-ground fault (LG), one conductor comes in contact with the ground or a neutral conductor. The line-to-line fault (LL) occurs when two conductors are short circuited. The double line-to-ground fault (LLG) occurs when two conductors make electrical contact with the ground or come in contact with the neutral conductor.

The process 200 then proceeds to step S208. When the fault is classified as the asymmetric fault, the process 200 proceeds to step S210 where parameters of the faulty line can be calculated. The parameters of the faulty line can include the V_{Si}, V_{Ri}, I_{Si}, and I_{Ri}, which are described at equations (9) and (10). The parameters of the faulty line can also include dV_{Sk}, dI_{Sk}, dV_{Rk} and dI_{Rk}, which are described at equations (1)-(4).

The process 200 then proceeds to S212 where the symmetrical components of the DL parameters, Z_{DLi} and Y_{DLi}, can be determined based on equations (9) and (10).

At step S214, the superposed quantities ΔV_{Si}, ΔV_{Ri}, ΔI_{Si}, and ΔI_{Ri} of the voltage signals and current signals of the DL can be identified based on equations (1)-(4). Subsequently, the equivalent source impedance Z_{SSi} and the equivalent load impedance Z_{SRi} are determined based on equations (7) and (8) respectively.

The process 200 proceeds to step S218 where the asymmetric impedance-based fault location method can be applied. The asymmetrical impedance-based fault location method leverages a sudden change of the system conditions resulted from the fault. The asymmetrical impedance-based fault location method is used to solve for the symmetrical components of voltages at the sending and receiving ends. The sudden change of voltage and current signals of the faulty DL shown in FIG. 1 can be defined by in the following fault location equations:

$$\begin{matrix} {V}_{S F i} = ( Δ {I}_{S i} - D Δ {V}_{S i} {Y}_{D L} ) ( \frac{{Z}_{SSi}}{1 + D {Z}_{SSi} {Y}_{D L}} + D {Z}_{D L} ) & ( 11 ) \\ {V}_{R F i} = ( Δ {I}_{R i} - ( L - D ) Δ {V}_{R i} {Y}_{D L} ) ( \frac{{Z}_{R S i}}{1 + ( L - D ) {Z}_{S S i} {Y}_{D L}} + ( L - D ) {Z}_{D L} ) & ( 12 )\end{matrix}$$

The sudden voltage change of the V_{SFi} at the sending terminal and the sudden voltage change of the V_{RFi} at the receiving terminal must be equal at the fault location when calculated from the sending and receiving terminals, respectively, when data of the two terminals is considered to be absolutely synchronous. The absolutely synchronous data can be obtained through synchronous measurement units, such as PMUs, which shows an advantage of applying PMUs for the fault location. Therefore, the asymmetric impedance-based fault location method can be described as follows:

$$\vert ( Δ {I}_{S i} - D Δ {V}_{S i} {Y}_{D L} ) ( \frac{{Z}_{S S i}}{1 + D {Z}_{S S i} {Y}_{D L}} + D {Z}_{D L} ) \vert = \vert ( Δ {I}_{R i} - ( L - D ) Δ {V}_{R i} {Y}_{D L} ) ( \frac{{Z}_{R S i}}{1 + ( L - D ) {Z}_{S S i} {Y}_{D L}} + ( L - D ) {Z}_{D L} ) \vert \qquad ( 13 )$$

The above fault location method described by (13) can be used to solve for D, which is the distance between the fault point and the sending bus. The solution can, also, be obtained graphically by plotting V_{SFi} and V_{RFi} for the full line length. An intersection point is the solution for the above fault location model and can provide the estimated D. Alternatively, the solution can be found through the following objective function:

D=min(|V_{SFi}|−V_{RFi}|) (14)

The process 200 then proceeds to step S220 where inaccuracy prediction measures can be applied, and subsequently proceeds to step S228 to print out the fault location of the fault.

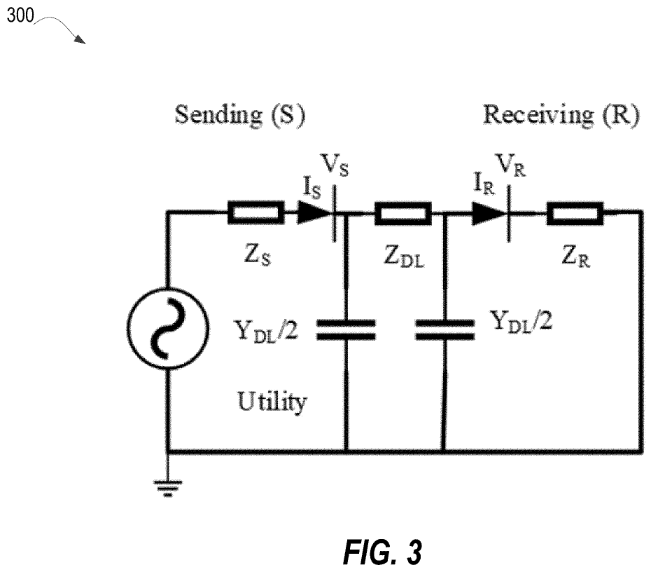

Still referring to FIG. 2, when the fault is classified as a symmetric fault, the process 200 proceeds to step S222 where parameters of the faulty line can be calculated. The parameters of the faulty line are illustrated in FIG. 3 which is a schematic diagram of a distribution network for symmetric algorithm. As shown in FIG. 3, j represents the phase (j=a, b and c). Z_{S} is an equivalent impedance at the sending end. Z_{R} is an equivalent impedance at the receiving end. Z_{DL} is an i^{th} sequence of distribution line impedance. Y_{DL} is an i^{th} sequence of distribution line admittance. V_{SPj} is a post-fault phase voltage at sending end. V_{RPj} is a post-fault phase voltage at receiving end. I_{SPj} is a post-fault line current at sending end. I_{RPj} is a post-fault line current at receiving end. L is a total distribution line length.

The process 200 subsequently proceeds to step S224 where the symmetrical impedance-based fault location method can be applied. In general, the symmetrical impedance-based fault location method analysis is less involved compared to the asymmetrical impedance-based fault location method. The symmetrical impedance-based fault location method can be derived based on the principle of voltage drop. First, the method identifies a voltage rise that is calculated from the receiving end by using the receiving end voltage and current and moving toward the sending terminal. Secondly, the method calculates a voltage reduction that moves from the sending end toward the receiving end by using the sending terminal quantities.

The symmetrical impedance-based fault location method performs fault location steps by using post-fault phase quantities, and applying the fault location steps to the pre-fault circuit arrangement (i.e., assuming there is no fault in the DL). The equations developed for symmetrical fault location can be described as follows:

V_{SFj}=V_{Spj}−(I_{Spj}−DV_{Spj}Y_{DL})DZ_{DL} (15)

V_{RFj}=V_{Rpj}+(I_{Rpj}−(L−D)V_{Rpj}Y_{DL})(L−D)Z_{DL} (16)

The calculated fault distance D can be obtained by one of the following equations:

|V_{SFj}|=|V_{RFj}|, solving for D (17)

D=first min(|V_{SFj}|−|V_{RFj}|) (18)

The process 200 then proceeds to step S226 where the inaccuracy prediction measures can be applied, and further to step S228 to print out a fault location of the fault.

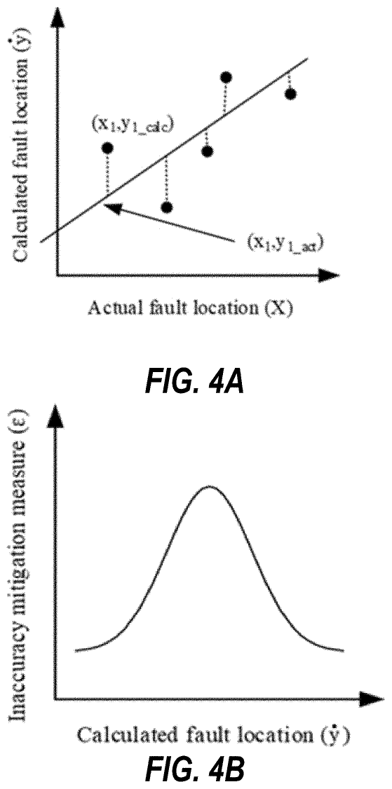

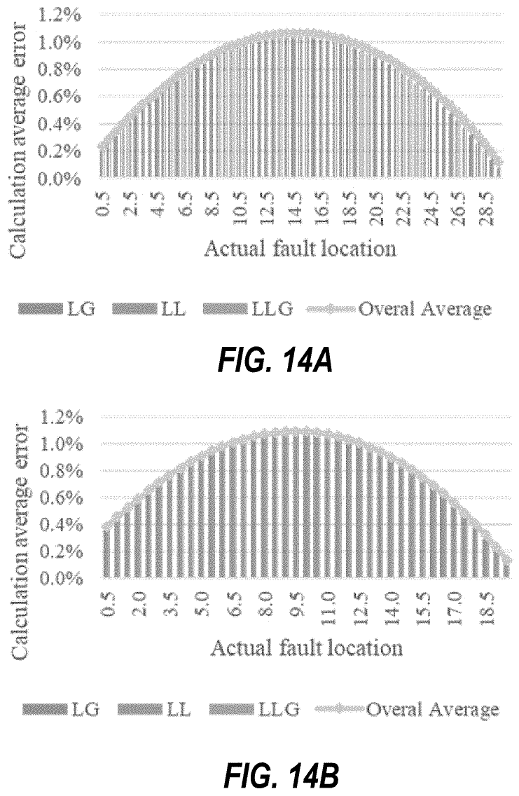

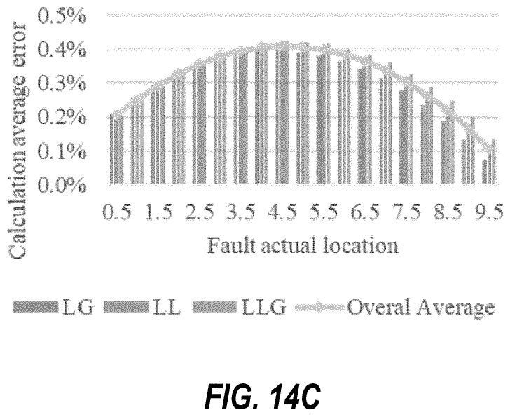

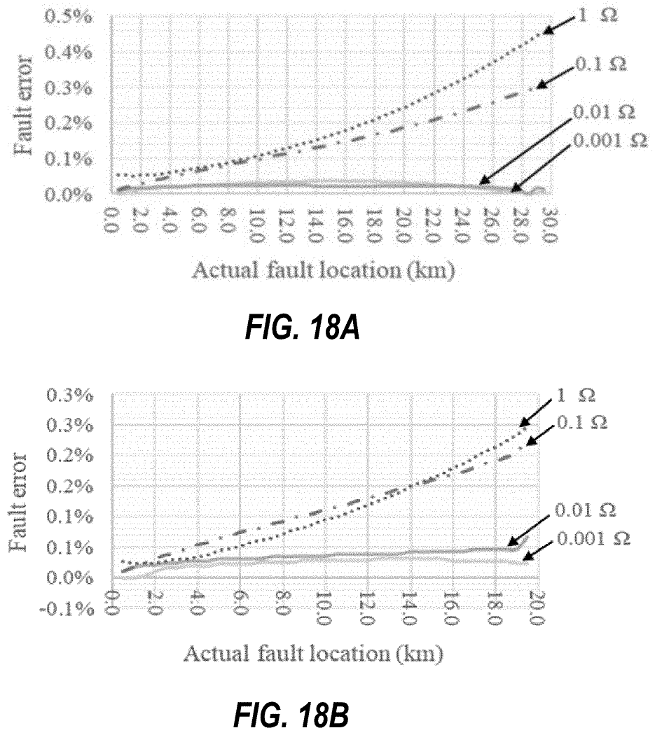

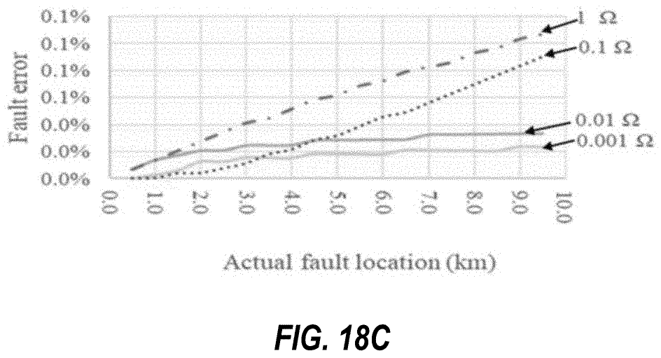

In the present disclosure, the steps S220 and S226 of the inaccuracy prediction measures can be demonstrated by FIGS. 4A-4B. FIG. 4A provides a correlation between an actual fault location and a calculated location that is obtained through the process 200. FIG. 4B provides inaccuracy mitigation measures. It is observed from the figures associated with Case I (base case without IMMs) in FIGS. 14 and 18 that an error follows a specific trend under different fault resistance and loading conditions. Knowing the error trend can ease the task of predicting a magnitude of the error and hence can mitigate the error. In the present disclosure, the inaccuracy mitigation measures are applied to improve the fault location accuracy. The measures are developed based on line characteristics and possible fault types and impedances. The inaccuracy mitigation measure concept is illustrated in FIGS. 4A-4B and given by the following formula:

ÿ=\dot{y}(1+ε(\dot{y})) (19)

Where \dot{y} is an originally calculated value and ÿ is an enhanced estimation. The symbol ε is taken from the pre-developed inaccuracy mitigation measures demonstrated in FIGS. 4A-4B. The inaccuracy mitigation curve can take different shapes based on line loadings and characteristics.

The inaccuracy mitigation measures (IMMs) can be organized into two categories. The first category can be a global-based inaccuracy mitigation measure (GIMM), which considers the average of all fault type errors for a specific case and under a specific algorithm. The second category can be a local-based inaccuracy mitigation measure (LIMM), which develops a specific measure for each fault type. The two IMMs can be developed for each of distribution lines as appropriate by the design consultant firms during the design phase of the lines, and part of the protection and coordination studies.

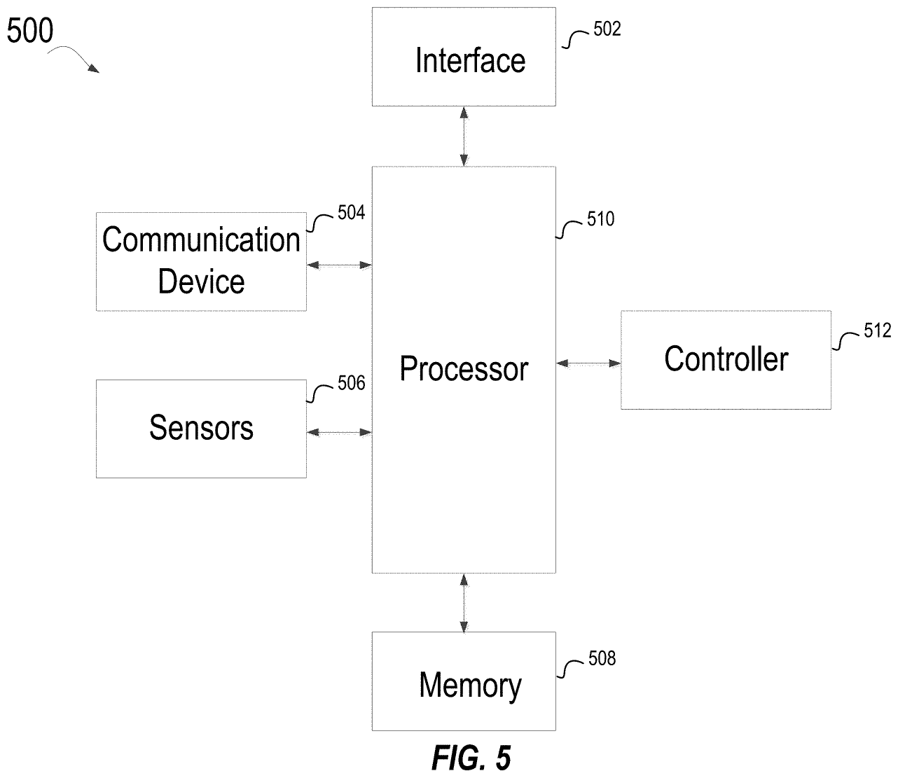

FIG. 5 is an apparatus 500 that can perform the impedance-based fault location model described by process 200. As shown in FIG. 5, the apparatus 500 can have an interface 502 that is configured to receive inputs form an operator, a communication device 504 configured to display a fault location determined based on the model described by process 200. The apparatus 500 can have a plurality of sensors 506. The sensors 506 can include the PMUs and other sensors. The apparatus 500 can also have a memory 508 configured to store signals sensed by the sensors 506. The apparatus 500 can have a processor 510 which is configured to receive the inputs from the operator via interface 512 and the signals from the sensors 506, and operate the process 200 to determine the fault location based on the signals and inputs. The apparatus 500 can further have a controller 512 that is configured to receive a determination made by the processor 510, and control the distribution grids accordingly.

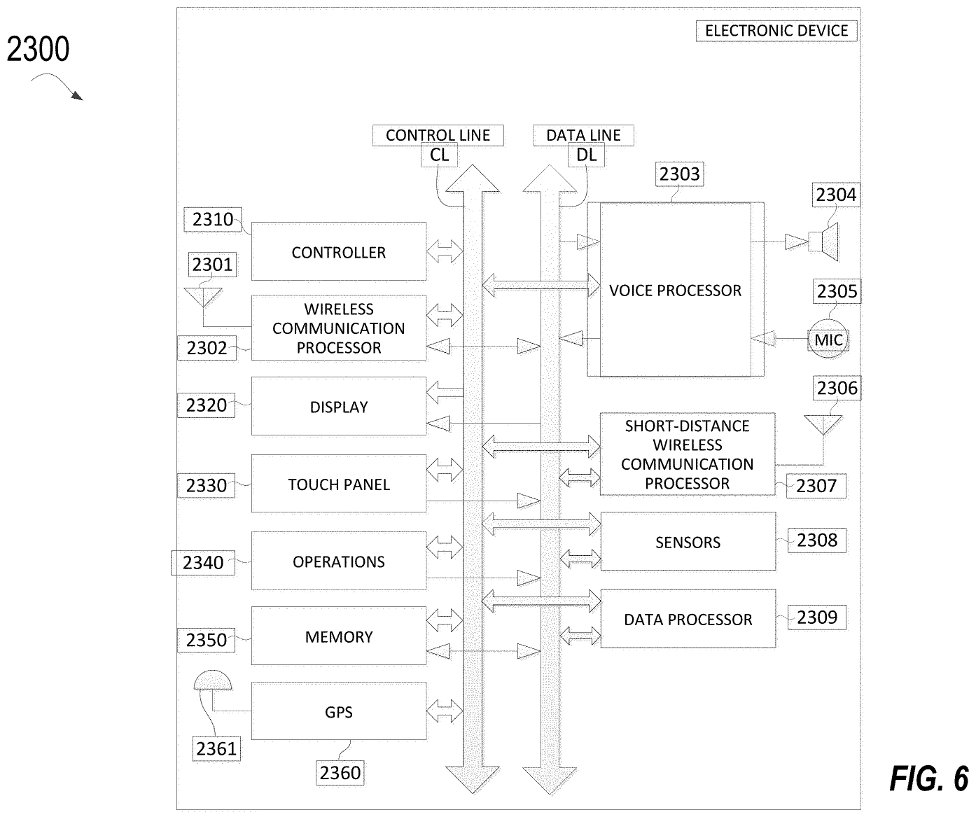

FIG. 6 is a block diagram illustrating an exemplary electronic device used in accordance with embodiments of the present disclosure. In an embodiment, electronic device 2300 can be used as the apparatus illustrated in FIG. 5 to perform the process 200.

The exemplary electronic device 2300 of FIG. 6 includes a controller 2310 and a wireless communication processor 2302 connected to an antenna 2301. A speaker 2304 and a microphone 2305 are connected to a voice processor 2303. The controller 2310 can include one or more Central Processing Units (CPUs), and can control each element in the electronic device 2300 to perform functions related to communication control, audio signal processing, control for the audio signal processing, still and moving image processing and control, and other kinds of signal processing. The controller 2310 can perform these functions by executing instructions stored in a memory 2350. Alternatively or in addition to the local storage of the memory 2350, the functions can be executed using instructions stored on an external device accessed on a network or on a non-transitory computer readable medium.

The memory 2350 includes but is not limited to Read Only Memory (ROM), Random Access Memory (RAM), or a memory array including a combination of volatile and non-volatile memory units. The memory 2350 can be utilized as working memory by the controller 2310 while executing the processes and algorithms of the present disclosure. Additionally, the memory 2350 can be used for long-term storage, e.g., of image data and information related thereto.

The electronic device 2300 includes a control line CL and data line DL as internal communication bus lines. Control data to/from the controller 2310 can be transmitted through the control line CL. The data line DL can be used for transmission of voice data, display data, etc.

The antenna 2301 transmits/receives electromagnetic wave signals between base stations for performing radio-based communication, such as the various forms of cellular telephone communication. The wireless communication processor 2302 controls the communication performed between the electronic device 2300 and other external devices via the antenna 2301. For example, the wireless communication processor 2302 can control communication between base stations for cellular phone communication.

The speaker 2304 emits an audio signal corresponding to audio data supplied from the voice processor 2303. The microphone 2305 detects surrounding audio and converts the detected audio into an audio signal. The audio signal can then be output to the voice processor 2303 for further processing. The voice processor 2303 demodulates and/or decodes the audio data read from the memory 2350 or audio data received by the wireless communication processor 2302 and/or a short-distance wireless communication processor 2307. Additionally, the voice processor 2303 can decode audio signals obtained by the microphone 2305.

The exemplary electronic device 2300 can also include a display 2320, a touch panel 2330, an operations key 2340, and an antenna 2306 connected to the short-distance communication processor 2307. The display 2320 can be a Liquid Crystal Display (LCD), an organic electroluminescence display panel, or another display screen technology. In addition to displaying still and moving image data, the display 2320 can display operational inputs, such as numbers or icons which can be used for control of the electronic device 2300. The display 2320 can additionally display a GUI for a user to control aspects of the electronic device 2300 and/or other devices. Further, the display 2320 can display characters and images received by the electronic device 2300 and/or stored in the memory 2350 or accessed from an external device on a network. For example, the electronic device 2300 can access a network such as the Internet and display text and/or images transmitted from a Web server.

The touch panel 2330 can include a physical touch panel display screen and a touch panel driver. The touch panel 2330 can include one or more touch sensors for detecting an input operation on an operation surface of the touch panel display screen. The touch panel 2330 also detects a touch shape and a touch area. Used herein, the phrase “touch operation” refers to an input operation performed by touching an operation surface of the touch panel display with an instruction object, such as a finger, thumb, or stylus-type instrument. In the case where a stylus or the like is used in a touch operation, the stylus can include a conductive material at least at the tip of the stylus such that the sensors included in the touch panel 2330 can detect when the stylus approaches/contacts the operation surface of the touch panel display (similar to the case in which a finger is used for the touch operation).

According to aspects of the present disclosure, the touch panel 2330 can be disposed adjacent to the display 2320 (e.g., laminated) or can be formed integrally with the display 2320. For simplicity, the present disclosure assumes the touch panel 2330 is formed integrally with the display 2320 and therefore, examples discussed herein can describe touch operations being performed on the surface of the display 2320 rather than the touch panel 2330. However, the skilled artisan will appreciate that this is not limiting.

For simplicity, the present disclosure assumes the touch panel 2330 is a capacitance-type touch panel technology. However, it should be appreciated that aspects of the present disclosure can easily be applied to other touch panel types (e.g., resistance-type touch panels) with alternate structures. According to aspects of the present disclosure, the touch panel 2330 can include transparent electrode touch sensors arranged in the X-Y direction on the surface of transparent sensor glass.

The touch panel driver can be included in the touch panel 2330 for control processing related to the touch panel 2330, such as scanning control. For example, the touch panel driver can scan each sensor in an electrostatic capacitance transparent electrode pattern in the X-direction and Y-direction and detect the electrostatic capacitance value of each sensor to determine when a touch operation is performed. The touch panel driver can output a coordinate and corresponding electrostatic capacitance value for each sensor. The touch panel driver can also output a sensor identifier that can be mapped to a coordinate on the touch panel display screen. Additionally, the touch panel driver and touch panel sensors can detect when an instruction object, such as a finger is within a predetermined distance from an operation surface of the touch panel display screen. That is, the instruction object does not necessarily need to directly contact the operation surface of the touch panel display screen for touch sensors to detect the instruction object and perform processing described herein. Signals can be transmitted by the touch panel driver, e.g. in response to a detection of a touch operation, in response to a query from another element based on timed data exchange, etc.

The touch panel 2330 and the display 2320 can be surrounded by a protective casing, which can also enclose the other elements included in the electronic device 2300. According to aspects of the disclosure, a position of the user's fingers on the protective casing (but not directly on the surface of the display 2320) can be detected by the touch panel 2330 sensors. Accordingly, the controller 2310 can perform display control processing described herein based on the detected position of the user's fingers gripping the casing. For example, an element in an interface can be moved to a new location within the interface (e.g., closer to one or more of the fingers) based on the detected finger position.

Further, according to aspects of the disclosure, the controller 2310 can be configured to detect which hand is holding the electronic device 2300, based on the detected finger position. For example, the touch panel 2330 sensors can detect a plurality of fingers on the left side of the electronic device 2300 (e.g., on an edge of the display 2320 or on the protective casing), and detect a single finger on the right side of the electronic device 2300. In this exemplary scenario, the controller 2310 can determine that the user is holding the electronic device 2300 with his/her right hand because the detected grip pattern corresponds to an expected pattern when the electronic device 2300 is held only with the right hand.

The operation key 2340 can include one or more buttons or similar external control elements, which can generate an operation signal based on a detected input by the user. In addition to outputs from the touch panel 2330, these operation signals can be supplied to the controller 2310 for performing related processing and control. According to aspects of the disclosure, the processing and/or functions associated with external buttons and the like can be performed by the controller 2310 in response to an input operation on the touch panel 2330 display screen rather than the external button, key, etc. In this way, external buttons on the electronic device 2300 can be eliminated in lieu of performing inputs via touch operations, thereby improving water-tightness.

The antenna 2306 can transmit/receive electromagnetic wave signals to/from other external apparatuses, and the short-distance wireless communication processor 2307 can control the wireless communication performed between the other external apparatuses. Bluetooth, IEEE 802.11, and near-field communication (NFC) are non-limiting examples of wireless communication protocols that can be used for inter-device communication via the short-distance wireless communication processor 2307.

The electronic device 2300 can include sensors 2308. The motion sensors 2308 can include PMUs to obtain the voltage and current signals of the DL.

Electronic device 2300 can include a data processor 2309, which is configured to receive the inputs from the operator via the touch panel 2330 and the signals from the sensors 2308, and operate a method, such as the method described by the process 200, to determine the fault location based on the signals and inputs.

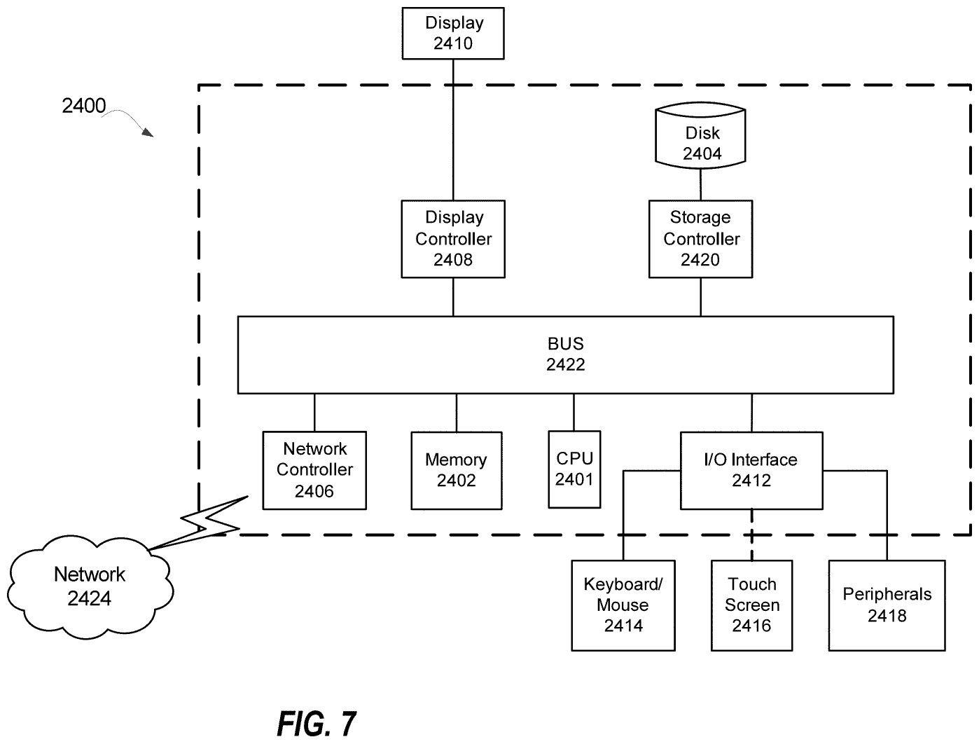

FIG. 7 is a block diagram of a hardware description of a computer 2400 used in exemplary embodiments. In the embodiments, computer 2400 can be a desk top, laptop, or server. The computer 2400 could be used as the processor 510 illustrated in FIG. 5.

As shown in FIG. 7, the computer 2400 includes a CPU 2401 which performs the processes described herein. The process data and instructions may be stored in memory 2402. These processes and instructions may also be stored on a storage medium disk 2404 such as a hard drive (HDD) or portable storage medium or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the computer 2400 communicates, such as a server or computer.

Further, the claimed advancements may be provided as a utility application, background daemon, or component of an operating system, or combination thereof, executing in conjunction with CPU 2401 and an operating system such as Microsoft® Windows®, UNIX®, Oracle® Solaris, LINUX®, Apple macOS® and other systems known to those skilled in the art.

In order to achieve the computer 2400, the hardware elements may be realized by various circuitry elements, known to those skilled in the art. For example, CPU 2401 may be a Xenon® or Core® processor from Intel Corporation of America or an Opteron® processor from AMD of America, or may be other processor types that would be recognized by one of ordinary skill in the art. Alternatively, the CPU 2401 may be implemented on an FPGA, ASIC, PLD or using discrete logic circuits, as one of ordinary skill in the art would recognize. Further, CPU 2401 may be implemented as multiple processors cooperatively working in parallel to perform the instructions of the inventive processes described above.

The computer 2400 in FIG. 7 also includes a network controller 2406, such as an Intel Ethernet PRO network interface card from Intel Corporation of America, for interfacing with network 2424. As can be appreciated, the network 2424 can be a public network, such as the Internet, or a private network such as LAN or WAN network, or any combination thereof and can also include PSTN or ISDN sub-networks. The network 2424 can also be wired, such as an Ethernet network, or can be wireless such as a cellular network including EDGE, 3G and 4G wireless cellular systems. The wireless network can also be WiFi®, Bluetooth®, or any other wireless form of communication that is known.

The computer 2400 further includes a display controller 2408, such as a NVIDIA® GeForce® GTX or Quadro® graphics adaptor from NVIDIA Corporation of America for interfacing with display 2410, such as a Hewlett Packard® HPL2445w LCD monitor. A general purpose I/O interface 2412 interfaces with a keyboard and/or mouse 2414 as well as an optional touch screen panel 2416 on or separate from display 2410. General purpose I/O interface 2412 also connects to a variety of peripherals 2418 including printers and scanners, such as an OfficeJet® or DeskJet® from Hewlett Packard.

The general purpose storage controller 2420 connects the storage medium disk 2404 with communication bus 2422, which may be an ISA, EISA, VESA, PCI, or similar, for interconnecting all of the components of the computer 2400. A description of the general features and functionality of the display 2410, keyboard and/or mouse 2414, as well as the display controller 2408, storage controller 2420, network controller 2406, and general purpose I/O interface 2412 is omitted herein for brevity as these features are known.

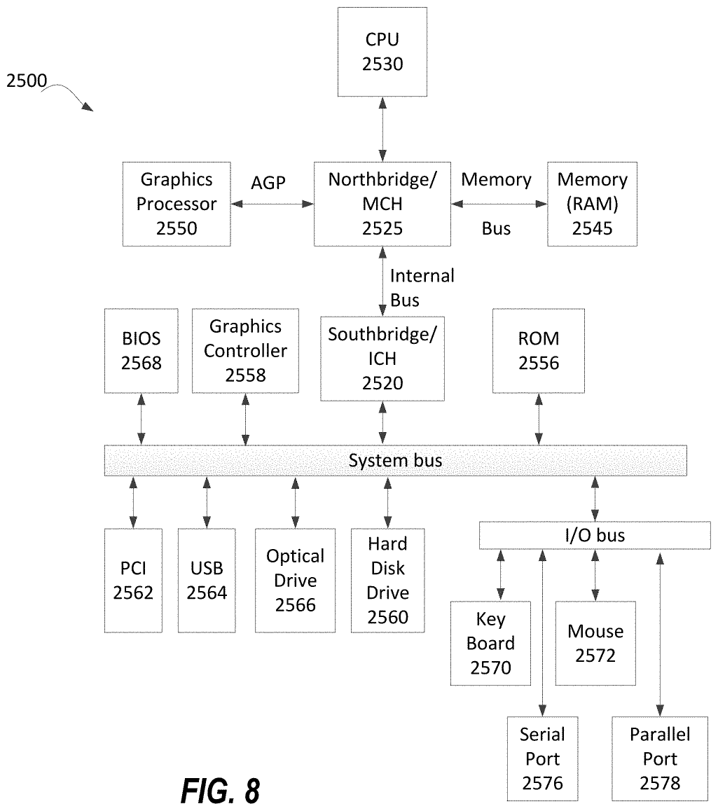

FIG. 8 is a schematic diagram of an exemplary data processing system. The data processing system is an example of a computer or a processor in which code or instructions implementing the processes of the illustrative embodiments can be located.

In FIG. 8, data processing system 2500 employs an application architecture including a north bridge and memory controller hub (NB/MCH) 2525 and a south bridge and input/output (I/O) controller hub (SB/ICH) 2520. The central processing unit (CPU) 2530 is connected to NB/MCH 2525. The NB/MCH 2525 also connects to the memory 2545 via a memory bus, and connects to the graphics processor 2550 via an accelerated graphics port (AGP). The NB/MCH 2525 also connects to the SB/ICH 2520 via an internal bus (e.g., a unified media interface or a direct media interface). The CPU 2530 can contain one or more processors and even can be implemented using one or more heterogeneous processor systems.

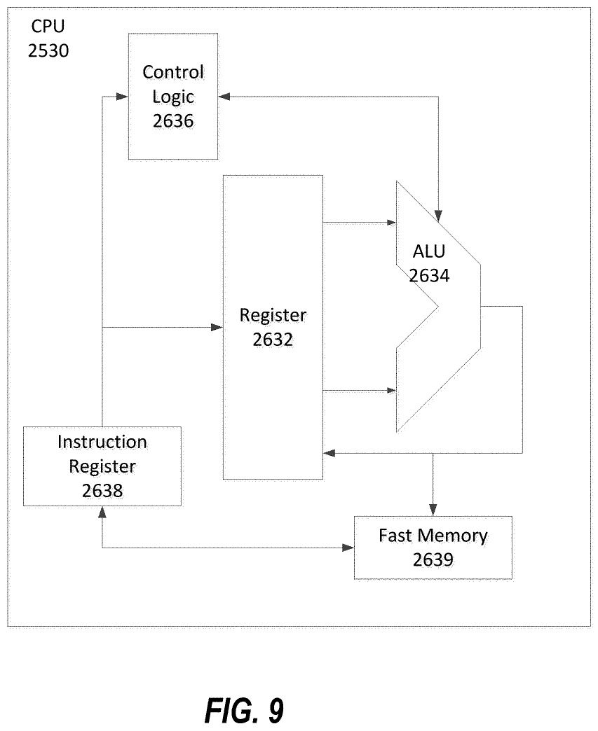

FIG. 9 illustrates an implementation of CPU 2530. In one implementation, an instruction register 2638 retrieves instructions from a fast memory 2639. At least part of these instructions are fetched from an instruction register 2638 by a control logic 2636 and interpreted according to the instruction set architecture of the CPU 2530. Part of the instructions can also be directed to a register 2632. In one implementation the instructions are decoded according to a hardwired method, and in another implementation the instructions are decoded according to a microprogram that translates instructions into sets of CPU configuration signals that are applied sequentially over multiple clock pulses. After fetching and decoding the instructions, the instructions are executed using an arithmetic logic unit (ALU) 2634 that loads values from the register 2632 and performs logical and mathematical operations on the loaded values according to the instructions. The results from these operations can be fed back into the register 2632 and/or stored in a fast memory 2639. According to aspects of the present disclosure, the instruction set architecture of the CPU 2530 can use a reduced instruction set computer (RISC), a complex instruction set computer (CISC), a vector processor architecture, or a very long instruction word (VLIW) architecture. Furthermore, the CPU 2530 can be based on the Von Neuman model or the Harvard model. The CPU 2530 can be a digital signal processor, an FPGA, an ASIC, a PLA, a PLD, or a CPLD. Further, the CPU 2530 can be an x86 processor by Intel or by AMD; an ARM processor; a Power architecture processor by, e.g., IBM; a SPARC architecture processor by Sun Microsystems or by Oracle; or other known CPU architectures.

Referring again to FIG. 8, the data processing system 2500 can include the SB/ICH 2520 being coupled through a system bus to an I/O Bus, a read only memory (ROM) 2556, universal serial bus (USB) port 2564, a flash binary input/output system (BIOS) 2568, and a graphics controller 2558. PCI/PCIe devices can also be coupled to SB/ICH 2520 through a PCI bus 2562.

The PCI devices can include, for example, Ethernet adapters, add-in cards, and PC cards for notebook computers. The Hard disk drive 2560 and CD-ROM 2566 can use, for example, an integrated drive electronics (IDE) or serial advanced technology attachment (SATA) interface. In one implementation the I/O bus can include a super I/O (SIO) device.

Further, the hard disk drive (HDD) 2560 and optical drive 2566 can also be coupled to the SB/ICH 2520 through a system bus. In one implementation, a keyboard 2570, a mouse 2572, a parallel port 2578, and a serial port 2576 can be connected to the system bus through the I/O bus. Other peripherals and devices can be connected to the SB/ICH 2520 using a mass storage controller such as SATA or PATA, an Ethernet port, an ISA bus, a LPC bridge, SMBus, a DMA controller, and an Audio Codec.

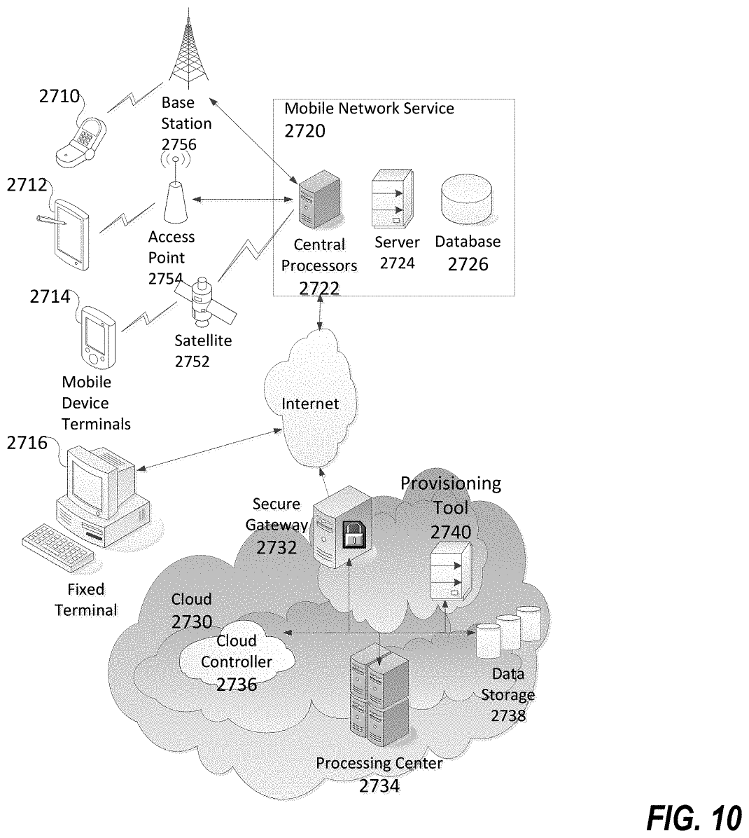

FIG. 10 illustrates an exemplary cloud computing system, where users access the cloud through mobile device terminals or fixed terminals that are connected to the Internet. The apparatus illustrated in FIG. 5 could be one of the mobile device terminals or one of the fixed terminals that are used in the cloud computing system illustrated in FIG. 10.

The mobile device terminals can include a cell phone 2710, a tablet computer 2712, and a smartphone 2714, for example. The mobile device terminals can connect to a mobile network service 2720 through a wireless channel such as a base station 2756 (e.g., an Edge, 3G, 4G, or LTE Network), an access point 2754 (e.g., a femto cell or WiFi network), or a satellite connection 2752. In one implementation, signals from the wireless interface to the mobile device terminals (e.g., the base station 2756, the access point 2754, and the satellite connection 2752) are transmitted to a mobile network service 2720, such as an EnodeB and radio network controller, UMTS, or HSDPA/HSUPA. Mobile users' requests and information are transmitted to central processors 2722 that are connected to servers 2724 to provide mobile network services, for example. Further, mobile network operators can provide service to mobile users for authentication, authorization, and accounting based on home agent and subscribers' data stored in databases 2726, for example. The subscribers' requests are subsequently delivered to a cloud 2730 through the Internet.

A user can also access the cloud through a fixed terminal 2716, such as a desktop or laptop computer or workstation that is connected to the Internet via a wired network connection or a wireless network connection. The mobile network service 2720 can be a public or a private network such as an LAN or WAN network. The mobile network service 2720 can be wireless such as a cellular network including EDGE, 3G and 4G wireless cellular systems. The wireless mobile network service 2720 can also be Wi-Fi, Bluetooth, or any other wireless form of communication that is known.

The user's terminal, such as a mobile user terminal and a fixed user terminal, provides a mechanism to connect via the Internet to the cloud 2730 and to receive output from the cloud 2730, which is communicated and displayed at the user's terminal. In the cloud 2730, a cloud controller 2736 processes the request to provide users with the corresponding cloud services. These services are provided using the concepts of utility computing, virtualization, and service-oriented architecture.

In one implementation, the cloud 2730 is accessed via a user interface such as a secure gateway 2732. The secure gateway 2732 can for example, provide security policy enforcement points placed between cloud service consumers and cloud service providers to interject enterprise security policies as the cloud-based resources are accessed. Further, the secure gateway 2732 can consolidate multiple types of security policy enforcement, including for example, authentication, single sign-on, authorization, security token mapping, encryption, tokenization, logging, alerting, and API control. The cloud 2730 can provide to users, computational resources using a system of virtualization, wherein processing and memory requirements can be dynamically allocated and dispersed among a combination of processors and memories to create a virtual machine that is more efficient at utilizing available resources. Virtualization creates an appearance of using a single seamless computer, even though multiple computational resources and memories can be utilized according to increases or decreases in demand. In one implementation, virtualization is achieved using a provisioning tool 2740 that prepares and equips the cloud resources, such as the processing center 2734 and data storage 2738 to provide services to the users of the cloud 2730. The processing center 2734 can be a computer cluster, a data center, a main frame computer, or a server farm. In one implementation, the processing center 2734 and data storage 2738 are collocated.

Embodiments described herein can be implemented in conjunction with one or more of the devices described above with reference to FIGS. 6-10. Embodiments are a combination of hardware and software, and circuitry by which the software is implemented.

In the present disclosure, the accuracy of the proposed methods is evaluated using different statistical measures. The different statistical measures are applied to ensure that the measures can converge for various case studies disclosed in the present disclosure. That is, in case one statistical measure fails to perform in one of the case studies, the evaluation can be achieved by other measures.

In the present disclosure, a first step toward accepting or rejecting the disclosed method is assessing the accuracy of the method by using a percentage error given by the following equation:

$$Error ( \% ) = \frac{\vert Actual - Calculation \vert}{Line length} \times 100 \qquad ( 20 )$$

Secondly, the following statistical measures can be used to evaluate the performance of the impedance-based fault location method: a) the coefficient of determination (CoD), denoted by R². The range of coefficient of determination varies between 0 and 1. The higher the number used in the proposed formula the more descriptive and reflective it is of actual values. b) mean absolute deviation (MAD), which is the summation of the absolute deviation between the actual and calculated values over the number of records (or the length of the range). c) mean square error (MSE), which is considered as the most common error metric. It is mainly the summation of the squared errors over the number of records. e) root mean square error (RMSE), obtained by applying the square root to the RMSE. f) mean absolute percentage error (MAPE), which is the average of absolute errors over the actual records.

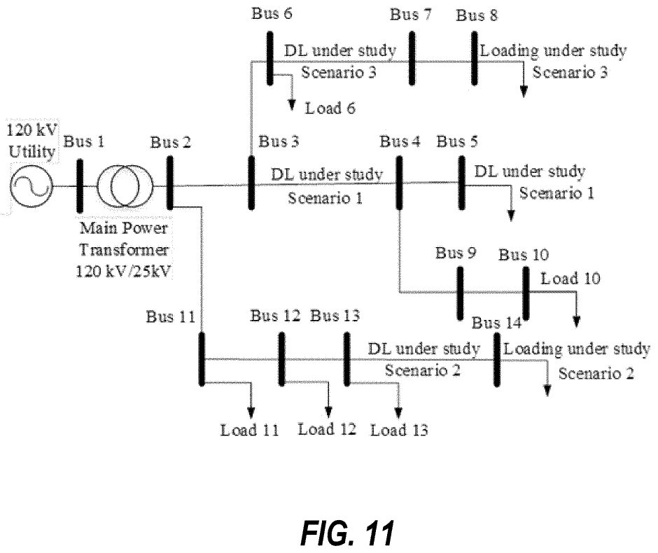

In the present disclosure, the effectiveness of the impedance-based fault location method can be validated by using 25 kV distribution systems shown in FIG. 11. A total of 7,254 different case studies were performed under three different scenarios that are summarized in Tables 1 and 2. The fault types include LG, double line (LL), double line-to-ground (LLG), and three-phase faults (LLLG). Different fault locations have been selected starting from 0.50 km to approximately the total line length with a step size of 0.5 km.

The large number of case studies is developed to test the robustness and accuracy of the proposed fault location model. The 7,254 simulations/case studies differ in the line lengths, fault locations, loading conditions, line parameters and applied IMMs.

The selected DL can be described as a structure of three-phase DL with a n-type. The structure includes of one set of resistance and inductance elements that are in series connected between sending and receiving terminals. Two sets of shunt capacitances that are lumped are also included at both ends as illustrated in FIGS. 1 and 3.

In MATLAB, two sets of simulated PMUs are placed at both terminals of the selected DL to measure the voltages and currents waveforms simultaneously. The recorded waveforms are in the shape of sinusoidal signals and then converted into phasor equivalents.

TABLE 1
Descriptions of the cases studies

| | Area of Case Study | | Additional |
|---|---|---|---|
| No. | Area | No. | Information/Reference |
| 1. | Unbalanced fault | 3 | LG, LL and LLG |
| 2. | Balanced fault | 1 | LLLG |
| 3. | Fault resistance (for | 6 | 0.001 Ω, 0.01 Ω, 0.1 Ω, 1 Ω, 10 |
| | asymmetrical) | | Ω and 100 Ω |
| 4. | Fault resistance | 4 | 0.001 Ω, 0.01 Ω, 0.1 Ω and 1 Ω |
| | (symmetrical) | | |
| 5. | Asymmetrical Case | 3 | 1) Without IMM, 2) GIMM, and |
| | | | 3) LIMM |
| 6. | Symmetrical Case | 2 | 1) Without and 2) with IMM |
| 7. | Fault placement | 117 | The fault placements starting |
| | | | from 0.50 km to approximately |
| | | | the total line length with a step |
| | | | size of 0.5 km. That is 59, 39 and |
| | | | 19 different fault locations for the |
| | | | three scenarios presented in |
| | | | Table 2, respectively. |
| Total | | 7,254 | (3 unbalanced fault) (6 fault |
| | | | resistances) (3 cases) (117 fault |
| | | | placements) + |
| | | | (1 balanced fault) (4 fault |
| | | | resistances) (2 cases) (117 fault |
| | | | placements) |

TABLE 2
Parameters of the different simulation scenarios

| | | Details | | |
|---|---|---|---|---|
| Specification | | Scenario 1 | Scenario 2 | Scenario 3 |
| Distribution line | | 30 | 20 | 10 |
| length (km) | | | | |
| Frequency (Hz) | | | 60 | |
| Loading | (MW) | 2 | 4 | 5 |
| | (MVar) | 0.5 | 2 | 3 |
| R | Positive & | 0.1153 | 0.0769 | 0.1153 |
| (Ω/km) | negative seq. | | | |
| | Zero-sequence | 0.413 | 0.2753 | 0.413 |
| L | Positive & | 1.05 × 10⁻³ | 0.0007 | 1.05 × 10⁻³ |
| (H/km) | negative seq. | | | |
| | Zero-sequence | 3.32 × 10⁻³ | 0.0022 | 3.32 × 10⁻³ |
| C | Positive & | 11.33 × 10⁻⁹ | 0.17 × 10⁻⁷ | 11.33 × 10⁻⁹ |
| (F/km) | negative seq. | | | |
| | Zero-sequence | 5.01 × 10⁻⁹ | 0.08 × 10⁻⁷ | 5.01 × 10⁻⁹ |

In the present disclosure, the simulation results of the 7,254 case studies can be organized into two categories: asymmetrical and symmetrical. Under each category, three simulation scenarios, which are shown in Table 2, are considered. In addition, three inaccuracy mitigation measures are applied: 1) case 1: base case, which includes the results obtained directly from the proposed fault location methods shown in FIG. 2 without applying the concept of IMM; 2) case 2: global-based inaccuracy mitigation measure (GIMM); 3) case 3: local-based inaccuracy mitigation measure (LIMM).

In the present disclosure, one inaccuracy mitigation measure is applied to the symmetrical impedance-based fault location method where the three phases and three phases to ground faults use the same balanced faults analysis.

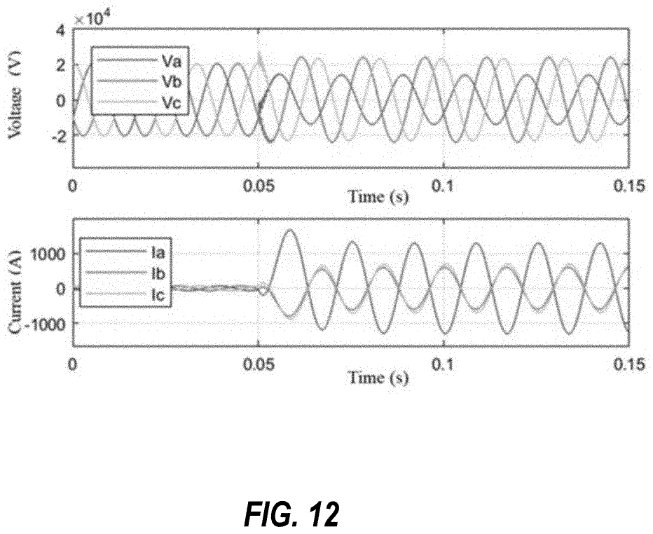

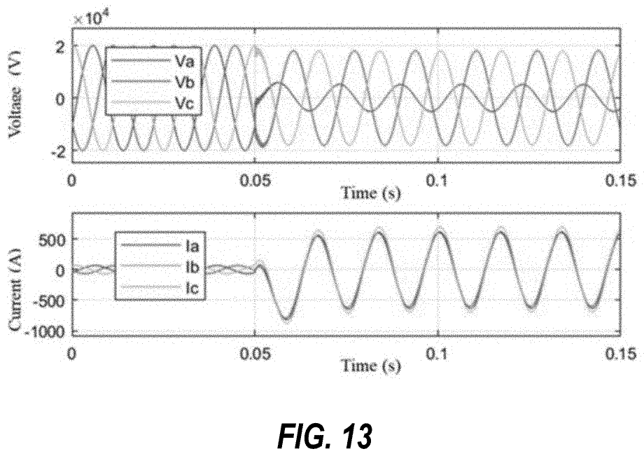

The calculation is performed based on the voltage and current signals obtained from PMUs that are installed at both ends of the line. FIG. 12 shows the voltage and current signals obtained from PMU devices at the sending end, and FIG. 13 shows the voltage and current signals obtained from PMU devices at the receiving end. In an embodiment, the DL considered is 30 km and the fault location is 25 km away from the sending bus at the 0.05 second. In FIGS. 12 and 13, a phase to ground fault, which is a sub case of line to ground fault, is applied. It is noticed that after 0.05 second, at both the sending and the receiving ends, a voltage of phase a Va is reduced and the current of phase a Ia is increased. This is a normal phenomenon during LG faults. FIGS. 12 and 13 show that certain models can be developed to detect a fault location of the fault.

Table 2 provides three scenarios that can be applied to three types of unbalanced/asymmetric faults (LG, LL and LLG). As shown in Table 2, the faults can be placed at different distances starting from 0.50 km to approximately the total line length with a step size of 0.5 km. In each fault distance, the fault resistance has been varied to be 0.001 Ω, 0.01Ω, 0.1Ω, 1Ω, 10Ω and 100Ω. The fault location at each distance has been averaged for the aforementioned fault resistance values.

Simulated results can be further applied with the three inaccuracy mitigation measures as mentioned above: 1) case 1: without IMM; 2) case 2: GIMM; and 3) case 3: LIMM.

The scenarios of Table 2 can be simulated by the proposed asymmetrical method for different fault distances and resistances. The average errors of fault resistances for fault distances and unbalanced fault types are demonstrated in FIGS. 14A-14C. FIG. 14A illustrates calculation average errors of fault resistance for the first scenario that is shown in table 2. FIG. 14B illustrates calculation average errors of fault resistance for the second scenario that is shown in Table 2. FIG. 14C illustrates calculation average errors of fault resistance for the third scenario that is shown in table 2.

The results in FIGS. 14A-14C reveal that the error curves follow a particular concaved-down parabolic graph. The parabolic shape is almost similar for all asymmetrical method related simulations with minor differences. Subsequently, the error can be predicted and hence mitigated.

Table 3 provides statistical measures results for all asymmetrical-based simulations (in %) that are categorized into fault types (LG, LL, and LLG).

TABLE 3

| | | LG | | | LL | | | LLG | | |
|---|---|---|---|---|---|---|---|---|---|---|
| | Statistical | Case | | | | | | | | |
| Scenario | Measure | 1 | 2 | 3 | 1 | 2 | 3 | 1 | 2 | 3 |
| 1 | MAD | 21.95 | 1.36 | 1.08 | 22.9 | 0.55 | 0.51 | 23.4 | 0.89 | 0.93 |
| | MSE | 5.53 | 0.03 | 0.02 | 5.97 | 0.00 | 0.00 | 6.17 | 0.02 | 0.02 |
| | RMSE | 23.49 | 1.58 | 1.25 | 24.4 | 0.62 | 0.57 | 24.8 | 1.09 | 1.13 |
| | MAPE | 2.55 | 0.09 | 0.07 | 2.60 | 0.05 | 0.05 | 2.62 | 0.07 | 0.07 |
| | R² | 99.9 | 100.0 | 100.0 | 99.9 | 100.0 | 100.0 | 99.9 | 100.0 | 100.0 |
| 2 | MAD | 23.50 | 0.92 | 0.77 | 24.0 | 0.40 | 0.40 | 24.3 | 0.67 | 0.67 |
| | MSE | 6.19 | 0.01 | 0.01 | 6.41 | 0.00 | 0.00 | 6.53 | 0.01 | 0.01 |
| | RMSE | 24.9 | 1.05 | 0.88 | 25.32 | 0.43 | 0.43 | 25.6 | 0.77 | 0.77 |
| | MAPE | 4.26 | 0.09 | 0.08 | 4.30 | 0.07 | 0.07 | 4.32 | 0.09 | 0.09 |
| | R² | 99.9 | 100.0 | 100.0 | 99.88 | 100.0 | 100.0 | 99.9 | 100.0 | 100.0 |
| 3 | MAD | 2.99 | 0.43 | 0.38 | 3.16 | 0.21 | 0.21 | 3.28 | 0.60 | 0.33 |
| | MSE | 0.10 | 0.00 | 0.00 | 0.11 | 0.00 | 0.00 | 0.12 | 0.00 | 0.00 |
| | RMSE | 3.14 | 0.49 | 0.43 | 3.29 | 0.22 | 0.22 | 3.40 | 0.65 | 0.36 |
| | MAPE | 1.06 | 0.09 | 0.08 | 1.08 | 0.08 | 0.08 | 1.10 | 0.17 | 0.10 |
| | R² | 99.9 | 99.99 | 100 | 99.9 | 100 | 100 | 99.9 | 99.9 | 100 |

Table 4 provides statistical measures results for all symmetrical-based simulations (in %) that are categorized into three scenarios.

TABLE 4

| | Scenario 1 | | Scenario 2 | | Scenario 3 | |
|---|---|---|---|---|---|---|
| Statistical | Case | | | | | |
| Measure | 1 | 2 | 1 | 2 | 1 | 2 |
| MAD | 2.92 | 2.61 | 2.07 | 1.54 | 1.04 | 0.73 |
| MSE | 0.19 | 0.10 | 0.08 | 0.04 | 0.02 | 0.01 |
| RMSE | 3.36 | 3.06 | 2.35 | 1.81 | 1.19 | 0.83 |
| MAPE | 0.24 | 0.20 | 0.24 | 0.16 | 0.21 | 0.16 |
| R² | 100.0 | 100.0 | 100 | 100 | 100 | 100 |

The maximum and average errors for the three scenarios considering the variation of both the distance and resistance of fault are displayed in Table 5. It is observed that the line length decreases as the maximum and average errors drops. The best numbers are obtained for the LG and LL and then for LLG. The base case overall average error for all scenarios is 0.62%, which reflects the accuracy of proposed asymmetrical fault location method by using PMUs.

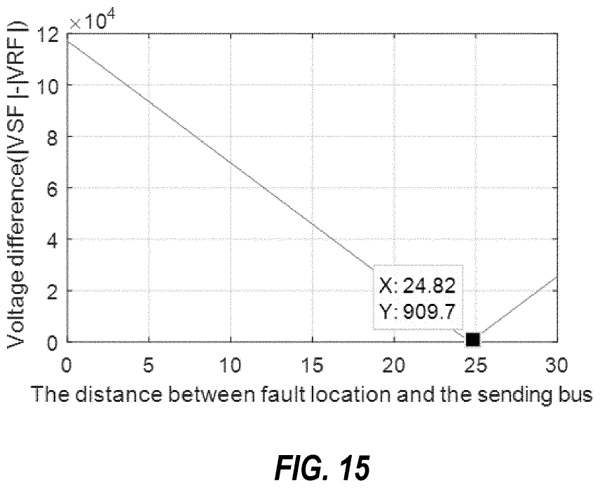

FIG. 15 represents an example of fault location solutions by using the proposed asymmetrical fault location algorithm. The line considered is 30 km and the fault location is 25 km away from the sending bus at the 0.05 second. The minimum point of (|V_{SFi}|−|V_{RFi}|) reflects the calculated fault distance from the sending bus.

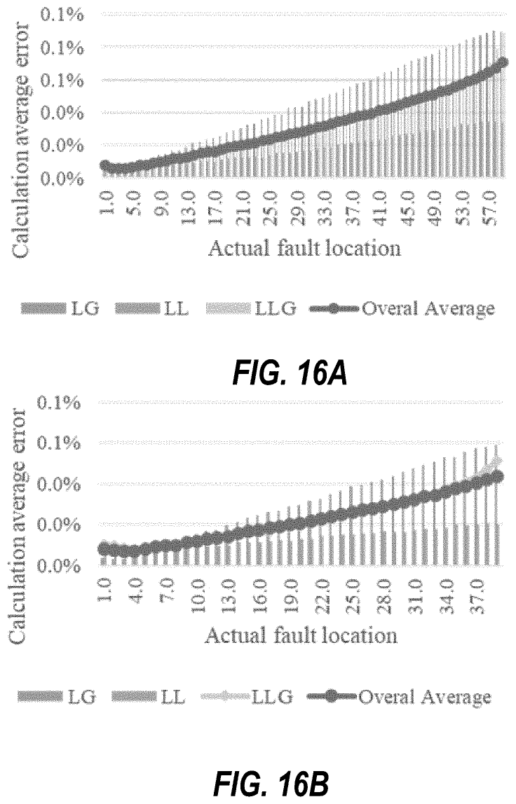

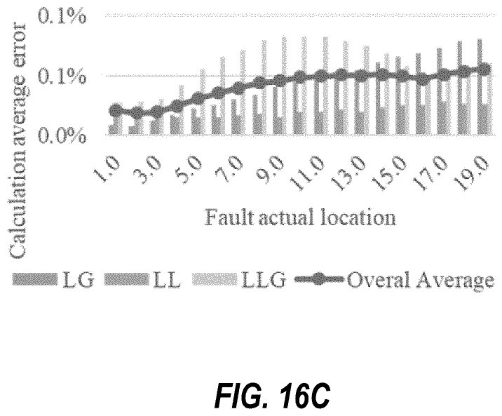

The GIMM considers the average of all unbalanced fault types errors for a specific scenario. This is under different loading conditions and the change of both distance and resistance of the fault. The results are averaged for fault resistances at specific distance and shown in FIGS. 16A-16C. FIG. 16A illustrates calculation average errors of fault resistance for the first scenario under the GIMM. FIG. 16B illustrates calculation average errors of fault resistance for the second scenario under the GIMM. FIG. 16C illustrates calculation average errors of fault resistance for the third scenario under the GIMM.

TABLE 5
Maximum and average errors for the three cases and scenarios considering the variation
of both distance and resistance of fault under asymmetrical conditions

| | | Error | | | | | | | |
|---|---|---|---|---|---|---|---|---|---|
| | | Maximum | | | | Average | | | |
| Case | Scen | LG | LL | LLG | Overall | LG | LL | LLG | Overall |
| 1 | 1 | 1.11 | 1.11 | 1.14 | 1.14 | 0.73 | 0.77 | 0.78 | 0.76 |
| | 2 | 1.12 | 1.12 | 1.13 | 1.13 | 0.78 | 0.80 | 0.81 | 0.80 |
| | 3 | 0.45 | 0.44 | 0.47 | 0.47 | 0.30 | 0.32 | 0.33 | 0.31 |
| 2 | 1 | 0.11 | 0.06 | 0.19 | 0.19 | 0.05 | 0.02 | 0.03 | 0.03 |
| | 2 | 0.07 | 0.05 | 0.14 | 0.14 | 0.03 | 0.01 | 0.02 | 0.02 |
| | 3 | 0.10 | 0.06 | 0.14 | 0.14 | 0.04 | 0.02 | 0.06 | 0.04 |
| 3 | 1 | 0.14 | 0.07 | 0.19 | 0.19 | 0.04 | 0.02 | 0.03 | 0.03 |
| | 2 | 0.08 | 0.05 | 0.11 | 0.11 | 0.03 | 0.01 | 0.02 | 0.02 |
| | 3 | 0.11 | 0.06 | 0.12 | 0.12 | 0.04 | 0.02 | 0.03 | 0.03 |

Global inaccuracy prediction and mitigation has tremendously enhanced fault location determination accuracy. The inaccuracy reduction could reach up to 96% of the base case. This is observed in the maximum error of LL fault under Scenario 2 as shown in Table 5 where the maximum error has been reduced from 1.12% to 0.0500 (above 22 times of reduction). In simple terminologies, the error for the base case is equivalent to 224 meters. By introducing the global inaccuracy prediction and mitigation, the uncertainty can drop to only 10 meters.

The overall average error obtained by the GIMM for all scenarios is 0.030%, which is over 20 times less than the base case. This proves the robustness and effectiveness of the disclosed GIMM.

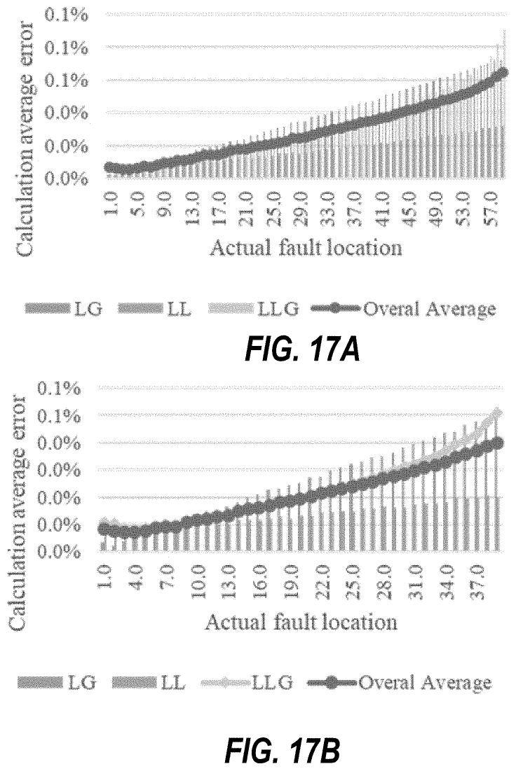

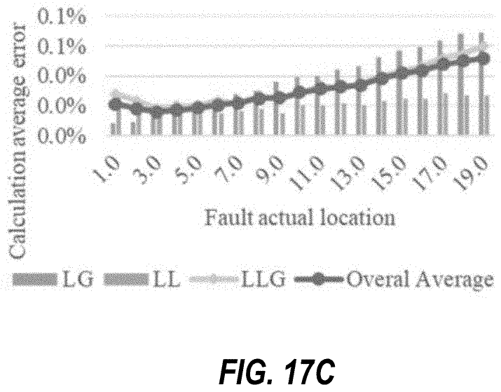

The LIMM is almost similar to the global IMM except that the LIMM uses a specific measure for each type of faults. The LIMM is developed based on the change of both distance and resistance of the fault. The results are averaged for fault resistances at specific distance and presented in FIG. 17.

The concept of local inaccuracy prediction and mitigation has resulted in a similar enhancement in the accuracy of fault location determination as is the case for global inaccuracy prediction and mitigation. The LIMM can achieve same level of reduction in inaccuracy as the GIMM, for example more than 22 times comparing to the case 1 (base case). The overall average error obtained by the LIMM measure for all scenarios is 0.027%. This number is less than both the base and global cases by 22.38 and 0.13 times, respectively. This proves the robustness and effectiveness of the LIMM. The symmetrical algorithms described in FIG. 2 can also be applied to different balanced faults for the three scenarios tabulated in Table 6. The faults were placed at different distances in the studied line starting from 0.50 km to approximately the total line length with a step size of 0.5 km. In each fault distance, the fault resistance was varied to be 0.001Ω, 0.01Ω, 0.1Ω and 1Ω.

The results are categorized into two cases: case 1 (base case) and case 2 (inaccuracy mitigation measures, IMM). The global IMM will be the same as the local IMM as the three phases and three phases to ground faults use the same balanced faults analysis.

TABLE 6
Maximum and average errors for the two cases and three
scenarios considering the variation of both distance
and resistance of fault under symmetrical conditions

| Case | Scenario | Maximum | Average |
|---|---|---|---|
| 1 | 1 | 0.46 | 0.10 |
| | 2 | 0.25 | 0.07 |
| | 3 | 0.11 | 0.03 |
| 2 | 1 | 0.26 | 0.09 |
| | 2 | 0.17 | 0.05 |
| | 3 | 0.09 | 0.02 |

The scenarios of Table 2 can be simulated by the symmetrical impedance-based fault location method for different fault distances and resistances. The average errors of fault resistances for fault distances and unbalanced fault types are demonstrated in FIGS. 18A-18C.

FIG. 18A illustrates calculated average errors of fault resistance for the first symmetric scenario without inaccuracy mitigation measures. FIG. 18B illustrates calculation average errors of fault resistance for the second symmetric scenario without inaccuracy mitigation measures. FIG. 18C illustrates calculation average errors of fault resistance for the third symmetric scenario without inaccuracy mitigation measures.

The results shown in FIGS. 18A-18C reveal that the error curves follow particular trends. The curvature trends are almost similar for the three scenarios. Therefore, the error can be predicted and hence mitigated.

The maximum and average errors for the three scenarios considering the variation of both the distance and resistance of fault can be displayed in Table 6. It is observed that the line length decreases as the maximum and average errors drops. The base case overall average error for all scenarios is 0.067%. This very low number reflects the high accuracy of proposed symmetrical fault location method by using PMUs.

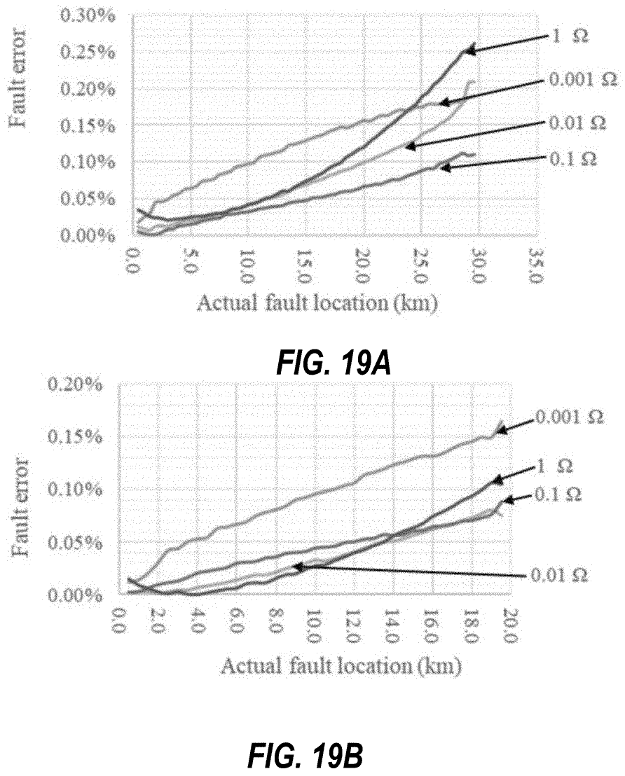

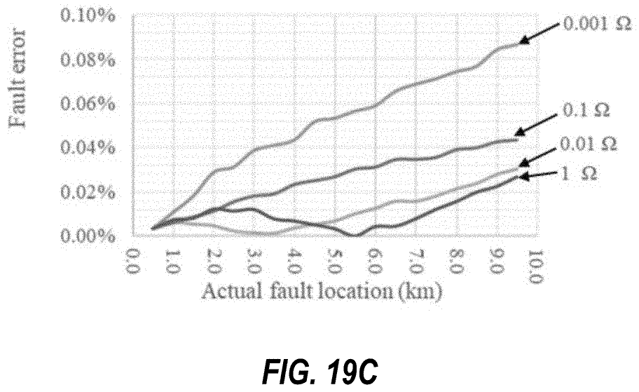

When the inaccuracy mitigation measures are applied, the resulted calculation errors of varying fault resistances for the three scenarios by using the proposed inaccuracy mitigation measure can be displayed in FIGS. 19A-19C. FIG. 19A illustrates calculation average errors of fault resistance for the first symmetric scenario under IMM. FIG. 19B illustrates calculation average errors of fault resistance for the second symmetric scenario under IMM. FIG. 19C illustrates calculation average errors of fault resistance for the third symmetric scenario under IMM.

The application of inaccuracy prediction and mitigation to the determination of fault location has provided an enhancement of the fault location accuracy. The inaccuracy reduction could reach up to 43% of the base case maximum errors and 29% of the average of the base case maximum errors. This confirms the robustness and effectiveness of the proposed inaccuracy mitigation measure.

Table 6 demonstrates the maximum and average errors for the three scenarios considering the variation of both distance and resistance of the faults.

In order to perform the model evaluation, the MAD, MSE, RMSE, MAPE and CoD can be applied to the three scenarios, three cases (i.e., case 1, case 2 and case3) and different resistance values. The results for the latter are averaged into one value for each scenario and each case. The results are tabulated in Table 3 and Table 6 to evaluate the robustness of the proposals. It is noticed from the Tables 3 and 6 that generally the values under the proposed IMMs categories are improved compared to those in the base case (Case1). This shows the strength of the proposed inaccuracy mitigation concept. Case 3 is superior to all cases and can provide very accurate results.

With the consideration of maximum and average errors presented in Table 5, the proposed IMMs concept is between 99.81% and 99.97%. The accuracy could reach more than four 9s if the minimum errors are considered.

Considering maximum and average errors shown in Table 6, the proposed IMMs concept is between 99.74% and 99.95%. The accuracy could reach more than four 9s if the minimum errors are considered.

The present disclosure provides a method and system to advance DL repair and system restoration which ensures prompt and accurate fault location determination. An impedance-based fault location method was developed and evaluated for different simulations by statistical measures. The method included an asymmetric impedance-based fault location method and a symmetric impedance-based fault location method. Additionally, global and local IMMs were proposed to improve the fault location. In the present disclosure, the proposed IMMs can significantly improve the fault location estimate up to 23 times compared to the base case without IMMs. The accuracies of the IMMs that are characterized through the maximum errors are 99.81% and 99.74% for the asymmetrical and symmetrical respectively. By applying the IMMs, fault location can be identified within a few meters of the exact location if not at the actual location. These accuracies demonstrate the effectiveness and the superiority of the proposed method comparing to related examples (see, J. Ren, S. S. Venkata, and E. Sortomme, “An Accurate Synchrophasor Based Fault Location Method for Emerging Distribution Systems,” IEEE Trans. Power Deliv., vol. 29, no. 1, pp. 297-298, February 2014; Z. Mengsheng, W. Yi, Z. Zhou, and Z. Li, “Research on fault location based on PMU for multi-source distribution network,” in Asia-Pacific Power and Energy Engineering Conference, APPEEC, 2016, vol. 2016-Decem, pp. 1877-1882). In the related examples mentioned above, a 99% of accuracy is disclosed, which is a highest accuracy for impedance-based fault location techniques in distribution networks by using PMUs among the related examples.

In the present disclosure, both the asymmetrical and symmetrical methods result in high-level of accuracy with overall average error of 0.62% and 0.067%, respectively. It is observed that the line length decreases as the maximum and average errors drops for both the symmetrical and asymmetrical methods. The two IMMs (i.e., GIMM and LIMM) can be developed for each line (DL) by design consultant firms during the design phase of the lines, and part of the protection studies. In addition, by calculating the line parameters online (in situ), the disclosed method does not suffer from the line impedance inaccuracy issues under the idea situation (homogeneous, radial, and uncompensated, etc.).

1. A method for predicting a fault location in a distribution system, comprising:
obtaining, by processing circuitry of an apparatus, voltage signals and current signals from phasor measurement units (PMUs) placed at two terminals of a distribution line (DL) in the distribution system, the two terminals including a sending terminal and a receiving terminal;
converting, by the processing circuitry, the voltage signals and current signals of the DL into phasors;
classifying, by the processing circuitry, a fault type of a faulty line of the DL in the distribution system based on the converted phasors, the fault type including a symmetric type and an asymmetric type;
predicting, by the processing circuitry, a fault location of the faulty line of the DL based on the fault type through an impedance-based fault location model; and
applying, by the processing circuitry, inaccuracy mitigation measures on the predicted fault location to improve a prediction accuracy.

2. The method of claim 1, when the fault type is the symmetric type, wherein predicting the fault location of the faulty line of the DL further comprises:
calculating parameters of the faulty lines; and
applying a symmetric method of the impedance-based fault location model on the calculated parameters to predict the fault location of the faulty line.

3. The method of claim 1, when the fault type is the asymmetric type, wherein predicting the fault location of the faulty line of the DL further comprising:
calculating parameters of the faulty lines;
determining symmetrical components of the voltage signals and current signals of the DL;
identifying superposed quantities of the voltage signals and current signals of the DL;
determining an equivalent impedance of a source and an equivalent impedance of a load in the faulty line of the DL; and
applying an asymmetric method of the impedance-based fault location model onto the calculated parameters, the identified symmetrical components, the determined superposed quantities, and the determined equivalent impedances to predict the fault location of the faulty line.

4. The method of claim 1, wherein the inaccuracy mitigation measures comprise:
ÿ=\dot{y}(1+ε(\dot{y})), \dot{y} being a originally predicted value of the fault location based on the impedance-based fault location model, ÿ being an enhanced prediction, and ε(\dot{y}) being taken from pre-developed inaccuracy mitigation measures in which the originally predicted value \dot{y} corresponds to a respective value of ε.

5. The method of claim 2, wherein the applying further comprises:
obtaining a sudden voltage change V_{SFj} at the sending terminal; and
obtaining a sudden voltage change V_{RFj} at the receiving terminal, where:
V_{SFj}=V_{SPj}−(I_{SPj}−DV_{SPj}Y_{DL})DZ_{DL},
V_{RFj}=V_{RPj}(I_{RPj}−(L−D)V_{RPj}Y_{DL})(L−D)Z_{DL},
j being a phase and equal to a, b, and c, V_{SPj} being a post-fault phase voltage at the sending terminal, I_{SPj} being a post-fault line current at the sending terminal, D being a distance of the fault form the sending terminal, Y_{DL} being a i^{th} sequence of a distribution line admittance, Z_{DL} being a i^{th} sequence of a distribution line impedance, V_{RPj} being a Post-fault phase voltage at the receiving terminal, I_{RPj} being a Post-fault line current at the receiving terminal, L being a total distribution line length.

6. The method of claim 5, wherein the applying further comprises at least one of:
letting |V_{SFj}|=|V_{RFj}|, and Solving for D; and
letting D=first min(|V_{SFj}|−|V_{RFj}|).

7. The method of claim 3, wherein the applying further comprises:
obtaining a sudden voltage change V_{SFi} at the sending terminal; and
obtaining a sudden voltage change V_{RFi} at the receiving terminal, where:
$${V}_{S F i} = ( Δ {I}_{S i} - D Δ {V}_{S i} {Y}_{D L} ) ( \frac{{Z}_{SSi}}{1 + D {Z}_{SSi} {Y}_{D L}} + D {Z}_{D L} ) , \\ {V}_{R F i} = ( Δ {I}_{R i} - ( L - D ) Δ {V}_{R i} {Y}_{D L} ) ( \frac{{Z}_{R S i}}{1 + ( L - D ) {Z}_{S S i} {Y}_{D L}} + ( L - D ) {Z}_{D L} ) ,$$
ΔI_{Si} being a i^{th} sequence of a superposed current at the sending terminal, D being a distance of the fault form the sending terminal, ΔV_{Si} being a i^{th} sequence of a superposed voltage at the sending terminal, Y_{DL} being a i^{th} sequence of a distribution line admittance, Y_{DL} being a i sequence of a distribution line admittance, Z_{SSi} being an equivalent impedance at the sending terminal, Z_{DL} being a i^{th} sequence of a distribution line impedance, ΔI_{Ri} being a i^{th} sequence of a superposed current at the receiving terminal, L being a total distribution line length, ΔV_{Ri} being a i^{th} sequence of superposed voltage at the receiving terminal, Z_{RSi} being an equivalent impedance at the receiving terminal.

8. The method of 7, wherein the applying further comprises at least one of:
solving the D by letting |V_{SFj}|=|V_{RFj}|; and
solving the D by letting D=min(|V_{SFj}|−|V_{RFj}|).

9. The method of claim 3, wherein determining the symmetrical components of the voltage signals and current signals of the DL comprises:
determining the symmetrical components Z_{DL} and Y_{DL} of the voltage signals and current signals based on a single measurement technique (SMT), where:
$${Z}_{D L i} = \frac{{V}_{Si}^{2} - {V}_{R i}^{2}}{{V}_{Ri} {I}_{Si} + {V}_{Si} {I}_{Ri}} ; and$$
$${Y}_{D L i} = \frac{2 ( {V}_{S i} - {V}_{Ri} )}{{I}_{Ri} + {I}_{Si}} ,$$
Z_{DLi} being a i^{th} sequence of distribution line impedance, V_{Si} being a i^{th} sequence of voltage collected from the PMUs at the sending terminal, V_{Ri} being a i^{t} sequence of voltage collected from the PMUs at the receiving terminal, I_{Si} being a i^{th} sequence of current collected from the PMUs at the sending terminal, I_{Ri} being a i^{th} sequence of current collected from the PMUs at the receiving terminal, Y_{DLi} being a i^{th} sequence of distribution line admittance.

10. The method of claim 3, wherein identifying the superposed quantities of the voltage signals and current signals of the DL comprises:
obtaining superposed phase voltage and current dV_{SK}, dV_{RK}, dI_{SK}, dI_{RK} at the sending and receiving terminals of the distribution line, K being phase a, b, or c, dV_{SK} being a phase voltage at the sending terminal, dv_{RK} being a phase voltage at the receiving terminal, dI_{SK} being a phase current at the sending terminal, dI_{RK} being a phase current at the receiving terminal; and
applying concepts of symmetrical components transformation method to obtain the superposed quantities ΔV_{Si}, ΔV_{Ri}, ΔI_{Si}, and ΔI_{Ri} of the voltage signals and current signals of the DL, where:
$$Δ {V}_{S i} = {M}^{- 1} \times d {V}_{Sk} , \\ Δ {V}_{R i} = {M}^{- 1} \times d {V}_{R k} , \\ Δ {I}_{S i} = {M}^{- 1} \times d {I}_{S k} , \\ Δ {I}_{R i} = {M}^{- 1} \times {dI}_{R k} , \\ {M}^{- 1} = \frac{1}{3} [ \begin{matrix}1 & 1 & 1 \\ 1 & a & {a}^{2} \\ 1 & {a}^{2} & a\end{matrix} ] ,$$
and
a=1e^{i120°}, M⁻¹ is a reciprocal of M, M is a symmetrical component transformation matrix.

11. The method of claim 10, wherein determining the equivalent impedance of the source Z_{SSi} and the equivalent impedance Z_{SRi} of the load in the faulty line of the DL comprises applying Kirchhoff Laws to determine the
$${Z}_{S S i} = \frac{Δ {V}_{Si}}{Δ {I}_{Si}} , and {Z}_{S R i} = \frac{Δ {V}_{R i}}{Δ {I}_{R i}} .$$

12. An apparatus for predicting a fault location in a distribution system, comprising:
processing circuitry configured to:
obtain voltage signals and current signals from phasor measurement units (PMUs) placed at two terminals of a distribution line (DL) in the distribution system, the two terminals including a sending terminal and a receiving terminal;
convert the voltage signals and current signals of the DL into phasors;
classify a fault type of a faulty line of the DL in the distribution system based on the converted phasors, the fault type including a symmetric type and an asymmetric type;
predict a fault location of the faulty line of the DL based on the fault type through an impedance-based fault location model; and
apply inaccuracy mitigation measures on the predicted fault location to improve a prediction accuracy.

13. The apparatus of claim 12, wherein the processing circuitry is configured to:
calculate parameters of the faulty lines; and
apply a symmetric method of the impedance-based fault location model on the calculated parameters to predict the fault location of the faulty line.

14. The apparatus of claim 12, wherein the processing circuitry is configured to:
calculate parameters of the faulty lines;
determine symmetrical components of the voltage signals and current signals of the DL;
identify superposed quantities of the voltage signals and current signals of the DL;
determine an equivalent impedance of a source and an equivalent impedance of a load in the faulty line of the DL; and
apply an asymmetric method of the impedance-based fault location model onto the calculated parameters, the identified symmetrical components, the determined superposed quantities, and the determined equivalent impedances to predict the fault location of the faulty line.

15. The apparatus of claim 12, wherein the inaccuracy mitigation measures comprise:
ÿ=\dot{y}(1+ε(\dot{y})), \dot{y} being a originally predicted value of the fault location based on the impedance-based fault location model, ÿ being an enhanced prediction, and ε(\dot{y}) being taken from pre-developed inaccuracy mitigation measures in which the originally predicted value \dot{y} corresponds to a respective value of ε.

16. The apparatus of claim 13, wherein the processing circuitry is configured to:
obtain a sudden voltage change V_{SFj} at the sending terminal; and
obtain a sudden voltage change V_{RFj} at the receiving terminal, where:
V_{SFj}=V_{SPj}−(I_{SPj}−DV_{SPj}Y_{DL})DZ_{DL},
V_{RFj}=V_{RPj}(I_{RPj}−(L−D)V_{RPj}Y_{DL})(L−D)Z_{DL},
j being a phase and equal to a, b, and c, V_{SPj} being a post-fault phase voltage at the sending terminal, I_{SPj} being a post-fault line current at the sending terminal, D being a distance of the fault form the sending terminal, Y_{DL} being a i^{th} sequence of a distribution line admittance, Z_{DL} being a i^{th} sequence of a distribution line impedance, V_{RPj} being a Post-fault phase voltage at the receiving terminal, I_{RPj} being a Post-fault line current at the receiving terminal, L being a total distribution line length.

17. The apparatus of claim 16, wherein the processing circuitry is further configured to:
let |V_{SFj}|=|V_{RFj}|, and solve for D; and
let D=first min(|V_{SFj}|−|V_{RFj}|).

18. The apparatus of claim 14, wherein the processing circuitry is further configured to:
obtain a sudden voltage change V_{SFi} at the sending terminal; and
obtain a sudden voltage change V_{RFi} at the receiving terminal, where:
$${V}_{S F i} = ( Δ {I}_{S i} - D Δ {V}_{S i} {Y}_{D L} ) ( \frac{{Z}_{SSi}}{1 + D {Z}_{SSi} {Y}_{D L}} + D {Z}_{D L} ) , \\ {V}_{R F i} = ( Δ {I}_{R i} - ( L - D ) Δ {V}_{R i} {Y}_{D L} ) ( \frac{{Z}_{R S i}}{1 + ( L - D ) {Z}_{S S i} {Y}_{D L}} + ( L - D ) {Z}_{D L} ) ,$$
ΔI_{Si} being a i^{th} sequence of a superposed current at the sending terminal, D being a distance of the fault form the sending terminal, ΔV_{Si} being a i^{th} sequence of a superposed voltage at the sending terminal, Y_{DL} being a i^{th} sequence of a distribution line admittance, Y_{DL} being a i sequence of a distribution line admittance, Z_{SSi} being an equivalent impedance at the sending terminal, Z_{DL} being a i^{th} sequence of a distribution line impedance, ΔI_{Ri} being a i^{th} sequence of a superposed current at the receiving terminal, L being a total distribution line length, ΔV_{Ri} being a i^{th} sequence of superposed voltage at the receiving terminal, Z_{RSi} being an equivalent impedance at the receiving terminal.

19. The apparatus of claim 18, wherein the processing circuitry is further configured to:
solve the D by letting |V_{SFj}|=|V_{RFj}|; and
solve the D by letting D=min(|V_{SFj}|−|V_{RFj}|).

20. A non-transitory computer-readable medium storing instructions which when executed by a computer cause the computer to perform:
obtaining voltage signals and current signals from phasor measurement units (PMUs) placed at two terminals of a distribution line (DL) in the distribution system, the two terminals including a sending terminal and a receiving terminal;
converting the voltage signals and current signals of the DL into phasors;
classifying a fault type of a faulty line of the DL in the distribution system based on the converted phasors, the fault type including a symmetric type and an asymmetric type;
predicting a fault location of the faulty line of the DL based on the fault type through an impedance-based fault location model; and
applying inaccuracy mitigation measures on the predicted fault location to improve a prediction accuracy.
